(19) United States
(12) Patent Application Publication
(10) Pub. No.: US 2009/0139576 A1
(43) Pub. Date: Jun. 4, 2009

(54) MICROFLUIDIC SYSTEMS, DEVICES AND METHODS FOR REDUCING NOISE GENERATED BY MECHANICAL INSTABILITIES

(75) Inventors: Hugh C. Crenshaw, Durham, NC (US); Jennifer Colonell, Belmont, MA (US); Daniel M. Hartmann, East Lansing, MI (US); Joshua T. Nevill, El Cerrito, CA (US); David W. Wyrick, Durham, NC (US)

Correspondence Address: EKSIGENT TECHNOLOGIES, LLC;c/o SHELDON MAK ROSE & ANDERSON, 100 East Corson Street, Third Floor, PASADENA, CA, 91103-3842, US

(73) Assignee: EKSIGENT TECHNOLOGIES, LLC, Dublin, CA (US)

(21) Appl. No.: 11/719,524

(22) PCT Filed: Aug. 10, 2006
(86) PCT No.: PCT/US06/31054

§ 371 Date: May 16, 2007

Related U.S. Application Data
(60) Provisional application No. 60/707,245, filed on Aug. 11, 2005.

(51) Int. Cl. G05D 11/03; B81B 7/04

(52) U.S. Cl. 137/3; 137/565.29; 137/597

(57) ABSTRACT

Microfluidic Systems, Devices and Methods for Reducing Noise Generated by Mechanical Instabilities. According to one embodiment, a microfluidic device is provided for reducing noise in a fluid mix. The microfluidic device can include microscale channels for passage of fluids to a mixing junction. The mixing channel can be adapted to combine the fluids into a common fluid flow. The microfluidic device can also include a connector channel including first and second ends. The first end of the connector channel can be connected to the mixing junction. The microfluidic device can also include an expansion channel having connection to the second end of the connector channel. The expansion channel can be adapted for passage of the fluid mix through the expansion channel to reduce concentration gradient noise of the fluid mix by dispersion of the fluid mix as the fluid mix passes through the expansion channel.

### CROSS-REFERENCE TO RELATED APPLICATIONS

This application claims the benefit of U.S. Patent Application Ser. No. 60/707,245, filed Aug. 11, 2005, the disclosure of which is incorporated herein by reference in its entirety. The disclosures of the following U.S. Provisional Applications, commonly owned and simultaneously filed Aug. 11, 2005, are all incorporated by reference in their entirety: U.S. Provisional Application entitled MICROFLUIDIC APPARATUS AND METHOD FOR SAMPLE PREPARATION AND ANALYSIS, U.S. Provisional Application No. 60/707,373 (Attorney Docket No. 447/99/2/1); U.S. Provisional Application entitled APPARATUS AND METHOD FOR HANDLING FLUIDS AT NANO-SCALE RATES, U.S. Provisional Application No. 60/707,421 (Attorney Docket No. 447/99/2/2); U.S. Provisional Application entitled MICROFLUIDIC BASED APPARATUS AND METHOD FOR THERMAL REGULATION AND NOISE REDUCTION, U.S. Provisional Application No. 60/707,330 (Attorney Docket No. 447/99/2/3); U.S. Provisional Application entitled MICROFLUIDIC METHODS AND APPARATUSES FOR FLUID MIXING AND VALVING, U.S. Provisional Application No. 60/707,329 (Attorney Docket No. 447/99/214); U.S. Provisional Application entitled METHODS AND APPARATUSES FOR GENERATING A SEAL BETWEEN A CONDUIT AND A RESERVOIR WELL, U.S. Provisional Application No. 60/707,286 (Attorney Docket No. 447/99/2/5); U.S. Provisional Application entitled MICROFLUIDIC SYSTEMS, DEVICES AND METHODS FOR REDUCING DIFFUSION AND COMPLIANCE EFFECTS AT A FLUID MIXING REGION, U.S. Provisional Application No. 60/707,220 (Attorney Docket No. 447/99/3/1); U.S. Provisional Application entitled MICROFLUIDIC SYSTEMS, DEVICES AND METHODS FOR REDUCING BACKGROUND AUTOFLUORESCENCE AND THE EFFECTS THEREOF U.S. Provisional Application No. 60/707,386 (Attorney Docket No. 447/99/3/3); U.S. Provisional Application entitled MICROFLUIDIC CHIP APPARATUSES, SYSTEMS, AND METHODS HAVING FLUIDIC AND FIBER OPTIC INTERCONNECTIONS, U.S. Provisional Application No. 60/707,246 (Attorney Docket No. 447/99/4/2); U.S. Provisional Application entitled METHODS FOR CHARACTERIZING BIOLOGICAL MOLECULE MODULATORS, U.S. Provisional Application No. 60/707,328 (Attorney Docket No. 447/99/5/1); U.S. Provisional Application entitled METHODS FOR MEASURING BIOCHEMICAL REACTIONS, U.S. Provisional Application No. 60/707,370 (Attorney Docket No. 447/99/5/2); U.S. Provisional Application entitled METHODS AND APPARATUSES FOR REDUCING EFFECTS OF MOLECULE ADSORPTION WITHIN MICROFLUIDIC CHANNELS, U.S. Provisional Application No. 60/707,366 (Attorney Docket No. 447/99/8); U.S. Provisional Application entitled PLASTIC SURFACES AND APPARATUSES FOR REDUCED ADSORPTION OF SOLUTES AND METHODS OF PREPARING THE SAME, U.S. Provisional Application No. 60/707,288 (Attorney Docket No. 447/99/9); U.S. Provisional Application entitled BIOCHEMICAL ASSAY METHODS, U.S. Provisional Application No. 60/707,374 (Attorney Docket No. 447/99/10); U.S. Provisional Application entitled FLOW REACTOR METHOD AND APPARATUS, U.S. Provisional Application No. 60/707,233 (Attorney Docket No. 447/99/11); and U.S. Provisional Application entitled MICROFLUIDIC SYSTEM AND METHODS, U.S. Provisional Application No. 60/707,384 (Attorney Docket No. 447/99/12).

### TECHNICAL FIELD

The subject matter disclosed herein relates to microfluidic systems, devices and methods for fabricating and using the same. More particularly, the subject matter disclosed herein relates to microfluidic systems and methods for reducing noise generated by mechanical instabilities.

### BACKGROUND ART

Microfluidic systems have been developed for miniaturizing and automating the acquisition of chemical and biochemical information, in both preparative and analytical capacities. These systems have resulted in decreased cost and improved data quality. Microfluidic systems typically include one or more microfluidic chips for conducting and mixing small amounts of fluid, reagent, or other flowable composition or chemical for reaction and observation. Microfluidic chips can be fabricated using photolithography, wet chemical etching, laser micromachining, and other techniques used for the fabrication of microelectromechanical systems. Generally, microfluidic systems can also include one or more computers, detection equipment, and pumps for controlling the fluid flow into and out of the chip for mixing two or more reagents or other fluids together at specific concentrations and observing any resulting reaction.

Typically, microfluidic chips include a central body structure in which various microfluidic elements are formed for conducting and mixing fluids. The body structure of the microfluidic chip can include an interior portion which defines microscale channels and/or chambers. Typically, two or more different fluids are advanced to a mixing junction or region at a controlled rate from their respective sources for mixing at desired concentrations. The mixed fluids can then be advanced to at least one main channel, a detection or analysis channel, whereupon the mixed fluids can be subjected to a particular analysis by detection equipment and analysis equipment, such as a computer.

A primary challenge in the design of microfluidic systems is the elimination or reduction of noise in the concentration of fluids mixed at the mixing junction. Noise in the fluid mix concentration is any deviation of the actual fluid mix concentration from the desired fluid mix concentration. This, in turn, affects the quality of data measured by the detection equipment downstream. The quality of data is dependent upon the observed signal-to-noise ratio (SNR). To obtain good analysis data, it is important that the different fluids are mixed in expected concentrations in accordance with an experiment design. It is desirable to reduce or eliminate noise in the fluid concentration at the mixing junction in order to obtain good analysis data in any downstream analysis. Noise in the fluid mix concentration can be introduced from a variety of sources in a microfluidic system. For example, noise can be introduced by temperature-dependent reagents that cause changes in chemical signals that produce apparent changes in the concentration of fluids as measured by a detector of that chemical signal. Additionally, noise can be introduced by thermal expansion or unexpected pressure-driven expansion of components of the microfluidic chip which can cause changes in volume that alter volumetric flow rates in the chip. Noise can also be introduced by thermal expansion or unexpected pressure-driven expansion of any components in the pumps that affect movement of, for example, the plunger relative to the barrel of a syringe pump. Noise can also be introduced by thermal expansion or unexpected pressure-driven expansion of any components in contact with the fluid in the system, such as any tubing that connects different components, such as the pumps and the microfluidic chip.

Noise commonly arises from mechanical instabilities in the microfluidic system. Pumps are the most common source of mechanical instabilities in a microfluidic system. Pump noise refers to noise in the signal that arises as a direct result of inaccuracies in the movement of the pumps that advance fluids in microfluidic systems. For example, in the case of servomotor-controlled, syringe-type pumps, a servomotor drives a linear translation stage that in turn pushes a syringe plunger, which drives fluid through the system. The motors that drive the pump can be operated to rotate at a set speed. Current servomotors tend to oscillate imperfectly around their set speeds. Any variations in motor speed and any “chatter” in moving parts of the pump, such as the translation stage or piston, can produce oscillations in the flow of one fluid independent of the intended flows for mixing the fluids, thus resulting in noise. Additionally, if the linear translation stage moves somewhat roughly along its rails, the syringe plunger will move the fluid through the system in a correspondingly rough fashion. Other types of motors and pumps can, similarly, introduce noise in the flow of a microfluidic system. Because these problems occur upstream from the mixing junction, noise can be introduced into the concentration of, the fluids mixed at the mixing junction.

Therefore, it is desirable to provide improved microfluidic systems, devices and methods for fabricating and using the same. It is also desirable to improve the design of microfluidic systems for reducing or eliminating any types of noise causing an undesired concentration of a fluid mix at a mixing junction. More specifically, it is desirable to reduce noise originating from mechanical instabilities, such as from pumps.

### SUMMARY

According to one embodiment, a microfluidic device and method is disclosed for reducing concentration gradient noise in a fluid mix. The microfluidic device can include a plurality of microscale channels for passage of fluids to a mixing junction. The mixing junction join the plurality of channels and provide an area for fluids passing in the channels to combine into a common fluid flow. Further, the microfluidic device can include a connector channel including first and second ends. The first end of the connector channel can be connected to the mixing junction. The fluids can mix laterally in the common fluid flow. An expansion channel can be connected to the second end of the connector channel. Further, the expansion channel can be adapted for passage of the fluid mix through the expansion channel to reduce concentration gradient noise of a fluid mix by dispersion of the fluid mix as the fluid mix passes through the expansion channel.

According to a second embodiment, a microfluidic device and method is disclosed for reducing concentration gradient noise. The microfluidic device can include a first substrate defining a microscale channel connected to a pump for receiving a fluid from the pump. The microfluidic device can also include a second substrate connected to the first substrate and including a flexible portion covering a portion of the microscale channel, the flexible portion being flexible in response to flow rate fluctuations of fluid from the pump for reducing concentration gradient noise.

According to a third embodiment, a microfluidic system and method is disclosed for reducing concentration gradient noise. The microfluidic system can include a microfluidic chip having a microscale channel and a detection channel connected to the microscale channel. The detection channel can include an expansion portion. The microfluidic system can also include a pump connected to the microscale channel for advancing a fluid including fluorophore to the detection channel. Further, the microfluidic system can include a fluorophore detector operable to detect fluorophore at the expansion portion of the detection channel.

According to a fourth embodiment, a microfluidic system and method is disclosed for reducing concentration gradient noise in a fluid. The microfluidic system can include a microfluidic chip including a detection channel for receiving a fluid having a fluorophore. The microfluidic system can also include a fluorophore detector operable to detect the fluorophore of the fluid at the detection channel and produce a fluorophore signal based on the detected fluorophore. Furthermore, the microfluidic system can include a filter connected to the fluorophore detector to filter predetermined frequencies in the fluorophore signal.

It is therefore an object to provide novel microfluidic systems, devices and methods for reducing noise in a concentration fluid mix generated by mechanical instabilities.

### BRIEF DESCRIPTION OF THE DRAWINGS

Exemplary embodiments of the presently disclosed subject matter will now be explained with reference to the accompanying drawings, of which:

FIG. 1 is a schematic diagram of an exemplary embodiment of a microfluidic system for generating and mixing continuous concentration gradients of fluids;

FIG. 2 is a schematic diagram of the channel and mixing region layout of a microfluidic chip;

FIG. 3 is an exemplary graph showing the noise generated by a first and second pump advancing fluid in a microfluidic system such as the system in FIG. 1;

FIG. 4 is a schematic diagram of the layout of a microfluidic chip including a serpentine channel for reducing noise in a concentration gradient;

FIG. 5 is an exemplary graph of the results of running variable concentration gradients in the microfluidic chip shown in FIG. 4;

FIG. 6 is another exemplary graph of the results of running variable concentration gradients in the microfluidic chip shown in FIG. 4;

FIG. 7A is a schematic diagram of an expansion channel and a corresponding graph showing the concentration gradient of a fluid as the fluid advances along the length of the expansion channel;

FIG. 7B is a schematic diagram of a plurality of outpockets and a corresponding graph showing the concentration gradient of a fluid as the fluid advances along the length of the expansion channel;

FIG. 8 is a schematic diagram of the layout of a microfluidic chip including an expansion channel for reducing noise in a concentration gradient;

FIG. 9 is another schematic diagram of the layout of a microfluidic chip including an expansion channel for reducing noise in a concentration gradient;

FIG. 10A is an exemplary graph showing noise generated by a first and second pump providing varying flow velocity profiles for fluids advanced by pumps in chip in the microfluidic chip shown in FIG. 8;

FIG. 10B is an exemplary graph showing the fluorescent signal measured immediately downstream from an expansion channel;

FIG. 11 is a schematic diagram of the layout of a portion of a microfluidic chip including flexible portions over channels for reducing noise due to mechanical instabilities;

FIG. 12 is a cross-sectional view of a portion of channels of the microfluidic chip shown in FIG. 11;

FIG. 13 illustrates an expansion channel of a microfluidic chip having a laser spot focused on an expansion channel by detection equipment;

FIG. 14 is a schematic diagram of the layout of an exemplary microfluidic chip including an expansion channel for detecting a fluorophore product;

FIG. 15 is a schematic diagram of the layout of a detection portion of a microfluidic chip;

FIG. 16 is a schematic diagram of an optical system for exciting both a product fluorophore and a fluorescent tracer dye;

FIG. 17 is a schematic diagram of an optical system for measuring light emitted by a product fluorophore and a fluorescent tracer dye;

FIG. 18 is a flow chart of an exemplary process for reducing concentration gradient noise in a microfluidic system by adding tracer dye to the fluids;

FIG. 19 is a flow chart of an exemplary process for correcting signals from two photodetectors;

FIG. 20 is a schematic diagram of an exemplary embodiment of a microfluidic chip including channels for introducing three fluids;

FIG. 21 is a schematic diagram of another exemplary embodiment of a microfluidic chip including channels for introducing three fluids;

FIG. 22 is a schematic top view of an embodiment of an analysis channel disclosed herein and upstream fluidly communicating microscale channels;

FIG. 23A is a schematic cross-sectional side view of an embodiment of analysis channel disclosed herein and upstream fluidly communicating microscale channel; and

FIG. 23B shows schematic cross-sectional cuts at A-A and B-B of the analysis channel of FIG. 23A.

### DETAILED DESCRIPTION

Microfluidic chips, systems, devices and related methods are described herein which incorporate improvements for reducing or eliminating noise in the fluid mix concentration. These microfluidic chips, systems, devices and methods are described with regard to the accompanying drawings. It should be appreciated that the drawings do not constitute limitations on the scope of the disclosed microfluidic chips, systems, and methods.

As used herein, the term “fluid” generally means any flowable medium such as liquid, gas, vapor, supercritical fluid, combinations thereof, or the ordinary meaning as understood by those of skill in the art.

As used herein, the term “vapor” generally means any fluid that can move and expand without restriction except for at a physical boundary such as a surface or wall, and thus can include a gas phase, a gas phase in combination with a liquid phase such as a droplet (e.g., steam), supercritical fluid, the like, or the ordinary meaning as understood by those of skill in the art.

As used herein, the term “reagent” generally means any flowable composition or chemistry. The result of two reagents combining together is not limited to any particular response, whether a biological response or biochemical reaction, a dilution, or the ordinary meaning as understood by those of skill in the art.

In referring to the use of a microfluidic chip for handling the containment or movement of fluid, the terms “in”, “on”, “into”, “onto”, “through”, and “across” the chip generally have equivalent meanings.

As used herein, the term “computer-readable medium” refers to any medium that participates in providing instructions to the processor of a computer for execution. Such a medium may take many forms, including but not limited to, non-volatile media, volatile media, and transmission media. Non-volatile media include, for example, optical or magnetic disks. Volatile media include dynamic memory, such as the main memory of a personal computer, a server or the like. Transmission media include coaxial cables; copper wire and fiber optics, including the wires that form the bus within a computer. Transmission media can also take the form of electric or electromagnetic signals, or acoustic or light waves such as those generated during radio frequency (RF) and infrared (IR) data communications. Common forms of computer-readable media include, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge, a carrier wave transporting data or instructions, or any other computer-readable medium. Various forms of computer readable media may be involved in carrying one or more sequences of one or more instructions to the processor for execution. Alternatively, hard-wired circuitry may be used in place of or in combination with software instructions to implement the subject matter. Thus, embodiments of the subject matter are not limited to any specific combination of hardware circuitry and software.

As used herein, the term “microfluidic chip,” “microfluidic system,” or “microfluidic device” generally refers to a chip, system, or device which can incorporate a plurality of interconnected channels or chambers, through which materials, and particularly fluid borne materials can be transported to effect one or more preparative or analytical manipulations on those materials. A microfluidic chip is typically a device comprising structural or functional features dimensioned on the order of mm-scale or less, and which is capable of manipulating a fluid at a flow rate on the order of several μl/min or less. Typically, such channels or chambers include at least one cross-sectional dimension that is in a range of from about 1 μm to about 500 μm. The use of dimensions on this order allows the incorporation of a greater number of channels or chambers in a smaller area, and utilizes smaller volumes of reagents, samples, and other fluids for performing the preparative or analytical manipulation of the sample that is desired.

Microfluidic systems are capable of broad application and can generally be used in the performance of biological and biochemical analysis and detection methods. The systems described herein can be employed in research, diagnosis, environmental assessment and the like. In particular, these systems, with their micron and submicron scales, volumetric fluid control systems, and integratability, can generally be designed to perform a variety of fluidic operations where these traits are desirable or even required. In addition, these systems can be used in performing a large number of specific assays that are routinely performed at a much larger scale and at a much greater cost.

A microfluidic device or chip can exist alone or may be a part of a microfluidic system which, for example and without limitation, can include: pumps for introducing fluids, e.g., samples, reagents, buffers and the like, into the system and/or through the system; detection equipment or systems; data storage systems; and control systems for controlling fluid transport and/or direction within the device, monitoring and controlling environmental conditions to which fluids in the system are subjected, e.g., temperature, current and the like.

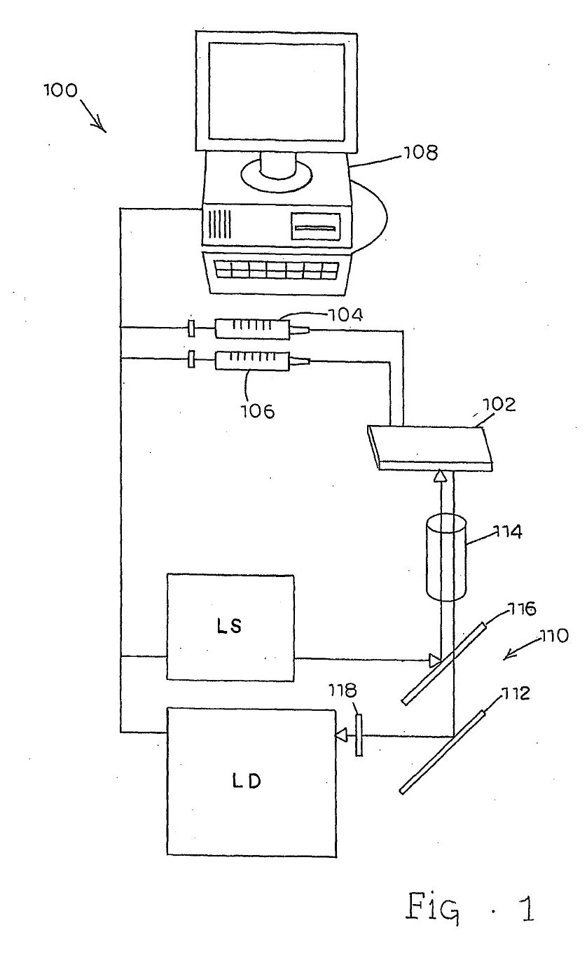

A schematic diagram of an exemplary embodiment of a microfluidic system, generally designated 100, for generating and mixing continuous concentration gradients of fluids is illustrated in FIG. 1. System 100 can include a microfluidic chip 102 having fluid connection to a first and second microfluidic pump 104 and 106 for advancing fluids through chip 102 for mixing and analysis. In this embodiment, pumps 104 and 106 are syringe pumps, which can be driven by servo motors. Alternatively, pumps 104 and 106 can comprise peristaltic pumps, pressure-driven pumps, conducting polymer pumps, electro-osmotic pumps, bubble pumps, piezo-electric driven pumps, or another type of pump suitable for pumping fluids through microfluidic chips. Pumps 104 and 106 can produce volumetric flow rates that are individually controllable by a computer 108.

According to one embodiment, computer 108 can be a general-purpose computer including a memory, or other suitable computer-readable medium, for storing program instructions for operating pumps 104 and 106. Alternatively, computer 108 can include a disk drive, compact disc drive, or other suitable component for reading instructions contained on a computer-readable medium for operating pumps 104 and 106. Further, computer 108 can include instructions for receiving, analyzing, and displaying information received from detection equipment, generally designated 110, described in further detail below. Computer 108 can also include a display, mouse, keyboard, printer, or other suitable component known to those of skill in the art for receiving and displaying information to an operator.

Computer 108 can operate pumps 104 and 106 to produce smooth, continuous flows in a stable manner. As known to those of skill in the art, some pumps can produce volumetric flow rates as low as approximately 1 nanoliter per minute. As described further herein, pumps 104 and 106 can be controlled to produce a fluid mix at a mixing junction in microfluidic chip 102 that has a continuously varied ratio over time for producing continuous concentration gradients at the mixing junction. As stated above, mechanical instabilities in and thermal expansion of syringe pumps and other components can introduce noise into the fluid mix concentration.

After mixing, a fluid mixture can be advanced to a detection channel/region, or analysis channel/region, on chip 102 and subjected to analysis by detection equipment 110. Typically, the mixed fluids travel a length of channel before reaching the detection channel/region to enable passive mixing of the fluids and sufficient interaction of the components of the fluids, such as reacting biochemicals. The detection channel/region can include a point at which measurement, e.g., concentration, of the fluid mixture is measured by a suitable data acquisition technique. Detection equipment 110 can be operably connected to computer 108 for receiving and storing the measurement acquired at the detection channel/region. Computer 108 can also perform analysis of measurement from detection equipment 110 and present an analysis of the measurement to an operator in a human-readable form. As fluid passes the detection channel/region, the fluid can flow to any suitable waste site for disposal.

A microfluidic chip, such as chip 102, can comprise a central body structure in which the various microfluidic elements are disposed. The body structure can include an exterior portion or surface, as well as an interior portion which defines the various microscale channels, fluid mixing regions, and/or chambers of the overall microscale device. For example, the body structures of microfluidic chips typically employ a solid or semi-solid substrate that is typically planar in structure, i.e., substantially flat or having at least one flat surface. Suitable substrates can be fabricated from any one of a variety of materials, or combinations of materials. Typically, the planar substrates are manufactured using solid substrates common in the fields of microfabrication, e.g., silica-based substrates, such as glass, quartz, silicon, or polysilicon, as well as other known substrates, such as sapphire, zinc oxide alumina, Group III-V compounds, gallium arsenide, and combinations thereof. In the case of these substrates, common microfabrication techniques such as photolithographic techniques, wet chemical etching, micromachining, i.e., drilling, milling and the like, can be readily applied in the fabrication of microfluidic devices and substrates. Alternatively, polymeric substrates materials can be used to fabricate the devices described herein, including, e.g., polydimethylsiloxanes (PDMS), polymethylmethacrylate (PMMA), polyurethane, polyvinylchloride (PVC), polystyrene polysulfone, polycarbonate, polymethylpentene, polypropylene, polyethylene, polyvinylidine fluoride, ABS (acrylonitrile-butadiene-styrene copolymer), cyclic olefin copolymer (COC), and the like. In the case of such polymeric materials, laser ablation, injection molding, or embossing methods can be used to form the substrates having the channels and element geometries as described herein. For injection molding and embossing, original molds can be fabricated using any of the above described materials and methods.

Channels, fluid mixing regions and chambers of microfluidic chips can be fabricated into one surface of a planar substrate, as grooves, wells, depressions, or other suitable configurations in that surface. A second planar substrate, typically prepared from the same or similar material, can be overlaid and bonded to the first, thereby defining and sealing the channels, mixing regions, and/or chambers of the device. Together, the upper surface of the first substrate, and the lower mated surface of the upper substrate, define the interior portion of the device, i.e., defining the channels, fluid mixing junctions, and chambers of the device. Alternatively, the surfaces of two substrates can be etched and mated together for defining the interior portion of the device.

Microfluidic chips typically include at least one detection channel, also termed an analysis channel, through which fluids are transported and subjected to a particular analysis. Fluid samples can be advanced from their respective sources to the detection channel by placing the fluids in channels that intersect at a fluid mixing junction. The fluids are suitably advanced through the channels at predetermined fluid velocities to achieve desired gradients of fluid concentration, also known as “concentration gradients,” at the mixing region. As referred to herein, a concentration gradient is a change in the concentration of a fluid in a space along some distance of the fluid in the space. As applied to microfluidic devices, for example, a concentration gradient can be considered the concentration change of a fluid along a length of a microfluidic channel. A concentration gradient can also be considered the concentration change over time of a fluid as it passes a point. Typical experiments can include varying the concentration gradients of fluids mixing in the mixing region and observing the resulting mixed fluids at a downstream detection channel. In order to obtain good analysis data, it is important to precisely control the flow rates of fluids at the mixing region. Unanticipated or uncontrolled motions of the fluid can alter the shape of the resulting concentration gradient. Even very small movements of the fluid (equaling volumes of only one nanoliter for example) that would be insignificant for larger systems can be problematic, due to the very slow flow rates used in microfluidic devices. Noise in the concentration gradient can adversely affect analysis data. Concentration gradient noise can be observed as a fluctuating concentration of fluid where the concentration gradient should be constant or smoothly changing with respect to time or space.

In the embodiment of FIG. 1, detection equipment 110 can monitor the progress of resulting reactions of the mixed fluids at the detection channel via fluorescence. For example, as a reaction proceeds at the detection channel: fluorescence can increase due to generation of a fluorescent compound; fluorescence can decrease due to degradation of a fluorescent compound; fluorescence polarization can change due to changes in the rotational diffusion of a fluorescently-tagged molecule, e.g., during binding to a larger molecule; fluorescence lifetime can change due to changes in diffusional mobility or due to changes in chemical environment; and fluorescence wavelength (excitation and/or emission) can change. Similarly, absorption of light by a chemical can be measured or the reagent stream can be sent to a mass spectrometer to measure the amount of specific chemicals.

For fluorescence detection, a fluorescence microscope can be employed. Alternatively, any type of light path known to those of skill in the art can be employed. The excitation light sources can be any suitable light source LS, such as green Helium Neon (HeNe) lasers, red diode lasers, and diode-pumped solid state (DPSS) lasers (532 nanometers). Incandescent lamps and mercury and xenon arclamps in combination with chromatic filters or diffraction gratings with slits can also be used as excitation sources. Excitation sources can include combinations, such as multiple lasers or lasers combined with arclamps and/or with chromatic filters or diffraction gratings with slits. Detection equipment 110 can include a light detector LD for detecting the light reflecting from and/or passing through the detection channel/region where a reaction occurs. Avalanche photodiodes (APDs) and photo-multiplier tubes (PMTs) can also be used. Light source LS and light detector LD can be coupled to a microscope having mirrors 112, lenses 114, dichroic reflectors 116, and chromatic filters 118. Other optical configurations can be used, such as fiber optic delivery of light from the excitation source to the chip and from the sample in the chip to the photodetector.

Other methods for detection can include luminescence, variants of fluorescence (e.g., polarization fluorescence, time-resolved fluorescence, fluorescence emission spectroscopy, fluorescence (or Förster) resonance energy transfer), and other non-optical techniques using sensors placed into the fluid flow, such as pH or other ion-selective electrodes, conductance meters, and capture/reporter molecules.

Computer 108 can include hardware and/or software computer program products comprising computer-executable instructions embodied in computer-readable media for controlling pumps 104 and 106. Computer 108 can also control and analyze the measurements received from detection equipment 110. Computer 108 can provide a user interface for presenting measurements and analysis to an operator and receiving instructions from an operator. Certain concepts discussed herein relate to a computer program product, for causing computer 108 to control pumps 104 and 106, light source LS, and light detector LD. Different methods described herein for controlling the components of system 100 can be implemented by various computer program products. For example, a programmable card can be used to control pumps 104 and 106, such as a PCI-7344 Motion Control Card, available from National Instruments Corporation, Austin, Tex. Methods for controlling pumps 104 and 106 to achieve a desired concentration gradient and receive analysis data from detection equipment 110 can be programmed using C++, LABVIEW™ (available from National Instruments Corporation), or any other suitable software. Such a computer program product comprises computer-executable instructions and/or associated data for causing a programmable processor to perform the methods described herein. The computer-executable instructions can be carried on or embodied in computer-readable medium.

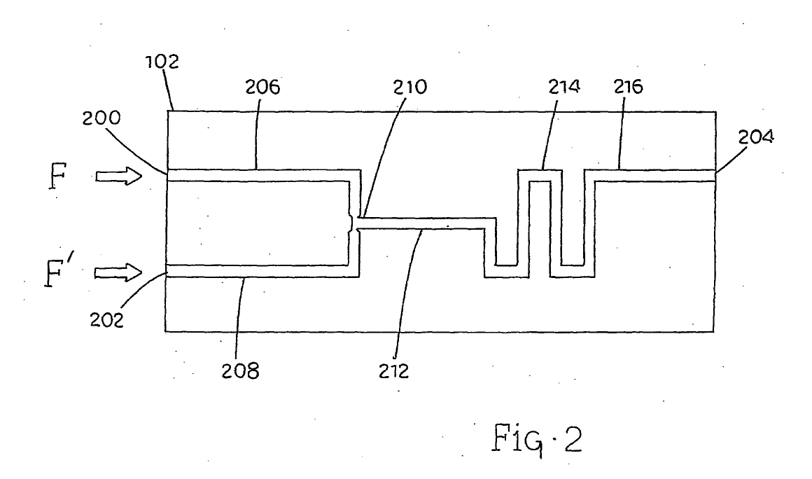

Referring to FIG. 2, a schematic diagram of the channel and mixing region layout of microfluidic chip 102 is illustrated. Microfluidic chip 102 can include two inputs 200 and 202 connected to pumps 104 and 106 (shown in FIG. 1), respectively, for advancing fluids F and F′ through the channels of chip 102. Fluids F and F′ from inputs 200 and 202, respectively, can be advanced by pumps 104 and 106, respectively, through premixing channels 206 and 208, respectively, and combined downstream at a fluid mixing junction 210. Premixing channels 206 and 208 can also function to equilibrate the temperature of fluids F and F′ in the channels to a surrounding temperature. In an alternative embodiment, microfluidic chip 102 can include more than two channels for combining more than two separate, and different if desired, fluids at the mixing junction or at multiple mixing junctions. The channels (such as premixing channels 206 and 208) described herein can be circular, semi-circular, rectangular, or nearly circular, semi-circular, or rectangular in cross-section.

In the embodiment of FIG. 2, microfluidic chip 102 can operate as a passive mixer such that all mixing occurs by diffusion. Therefore, microfluidic chip 102 can include a mixing channel 212 downstream from mixing junction 210 to allow fluids F and F′ to adequately mix prior to detection downstream. Alternatively, mixing can be enhanced by the inclusion of structures in the microfluidic channels that generate chaotic advection, or mixing can be actively performed by the inclusion of moving, mechanical stirrers such as magnetic beads driven by an oscillating magnetic field. Mixing junction 210 can be configured in any suitable configuration, such as what is known as a T-junction as shown in FIG. 2. The fluid streams from channels 206 and 208 therefore can combine laterally toward each other.

Microfluidic chip 102 can also include a serpentine channel 214 in communication with mixing channel 212 and positioned downstream therefrom. Serpentine channel 214 can operate as an aging loop for allowing a reaction to proceed for a period of time before reaching a detection channel 216. The length of an aging loop and the linear velocity of the fluid determine the time period of the reaction. Longer loops and slower linear velocities produce longer reactions. The lengths of aging loops can be tailored to a specific reaction or set of reactions, such that the reactions have time to complete during the length of the channel. Conversely, long aging loops can be used and shorter reaction times can be measured by detecting closer to mixing junction 210. Waste fluid can be removed from microfluidic chip 102 via waste channel 204.

An exemplary method for generating and mixing concentration gradients using microfluidic system 100 (shown in FIG. 1) will now be described hereinbelow. First, pumps 104 and 106 can be prepared with fluids and connected to microfluidic chip 102. Any suitable method can then be used to purge the channels of microfluidic chip 102 for removing any contaminants, bubbles, or any other substance affecting concentration. Further, configuration and calibration of detection equipment 110 can be effected.

Once microfluidic system 100 has been prepared, concentration gradients can be run through microfluidic chip 102. Pumps 104 and 106 can be activated to establish separate flows of separate, and different if desired, fluids into chip 102 for mixing and measurement. According to one embodiment, the total or combined volumetric flow rate established by the active pumps is maintained at a constant value during the run. In addition, the ratio of the individual flow rates established by respective pumps can be varied over time by individual control, thereby causing the resulting concentration gradient of the mixture to vary with time. The concentration gradient of interest is that of an analyte of interest relative to the other components of the mixture. The analyte of interest can be any form of reagent or component of a reagent. Exemplary reagents can include inhibitors, substrates, enzymes, fluorophores or other tags, and the like. As the reaction product passes through detection channel/region with varying concentration gradient, detection equipment 110 samples the resulting reaction flowing through at any predetermined interval. The measurements taken of the mixture passing through the detection channel/chamber can be temporally correlated with the flow ratio produced by pumps 104 and 106, and a response can be plotted as a function of time and concentration.

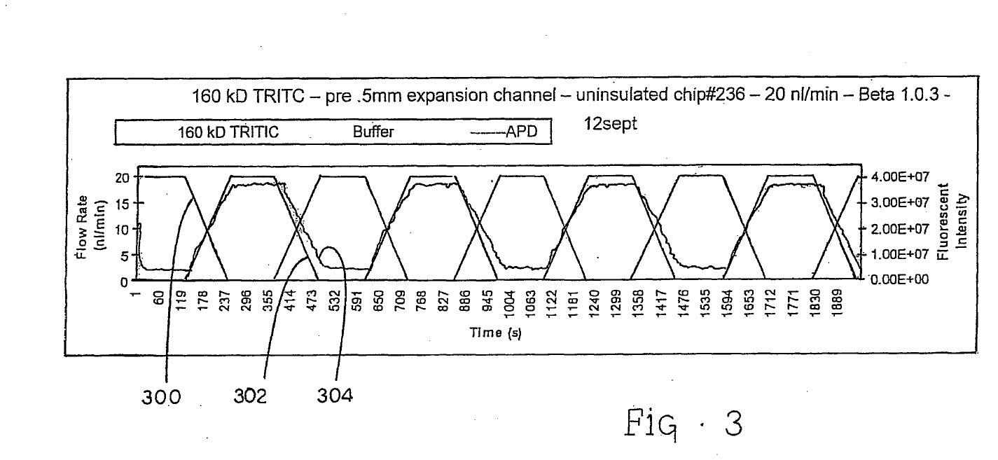

As stated above, mechanical instabilities, such as instabilities in fluid flow generated by pumps, such as pumps 104 and 106 shown in FIG. 1, can be a primary cause of poor data quality in conventional microfluidic systems. FIG. 3 illustrates an exemplary graph showing the noise generated by a first and second pump advancing fluid in a microfluidic system, such as system 100 shown in FIG. 1, combining fluids at a fluid mixing junction. Graph lines 300 and 302 represent varying flow velocity profiles of fluids advanced in the channels, such as first and second channels 206 and 208 shown in FIG. 2, respectively, by the pumps, such as first and second pumps 104 and 106, respectively. The graph shows that the total volumetric flow rate can be kept constant while varying concentration gradients over time, by increasing the flow rate of one pump while decreasing the flow rate of the other pump. For example, at time t=60, the flow rate associated with graph line 300 has the relative value of 100% of the total volumetric flow rate, and the flow rate associated with graph line 302 has the relative value of 0%. As the flow of the first pump (shown by graph line 300) is decreased and the flow rate of the second pump (shown by graph line 302) is increased, their profile lines cross at approximately time t=178, where each flow-rate is 50%. The flow rates in the first and second channels can be oscillated between 0% and 100%.

The graph also shows the resulting concentration gradient of fluorescent molecules at a mixing channel, such as mixing channel 212 shown in FIG. 2, over time and the noise associated with inaccuracies in pump flow rates. The fluid advanced in the first channel comprises a non-fluorescent buffer solution. The fluid advanced in the second channel includes a small concentration of fluorophore (550 nM 160 kD TRITC labeled Dextran, provided by Molecular Probes Inc. of Eugene, Oreg.). Graph line 304 represents the fluorescent signal measured by detection equipment downstream from a fluid mix region where the two fluids are mixed. As shown, the fluorescent signal (line 304) contains a substantial amount of noise resulting from inaccuracies in the syringe pump flow rates and from inaccuracies in other components as discussed above. Provided hereinbelow are microfluidic chips, devices, and related methods for reducing or eliminating the noise in chemical concentration gradients associated with mechanical instabilities resulting in inaccuracies in pump flow rates or from other sources of noise.

### Chip Geometries

As stated above, noise in a fluid mix concentration can result in poor data quality in microfluidic systems. This poor data quality is typically observed as a random series of locally steep concentration gradients in the mixed fluids. Steep concentration gradients can be reduced via molecular diffusion and dispersion. In a microfluidic system, molecular diffusion and dispersion can occur as a fluid advances through a microscale channel. Diffusion and dispersion transport the fluid from regions of high concentration to regions of low concentration, occur whenever the concentration gradient is non-zero, and decrease the magnitude of the concentration gradient.

Diffusion in the axial direction of a microfluidic channel can be seemingly greater than expected from molecular diffusion. This is because microfluidic channels have a parabolic velocity profile that is typical for laminar flow in a tube—the axial velocity is maximal and the velocity at the wall is zero. Thus, a concentration gradient experiences dispersion arising from both molecular diffusion and from distortion of the gradient by the velocity profile, a phenomenon called Taylor-Aris dispersion. Although not intending to be bound by theory, the chemical, therefore, appears to have a different axial diffusion coefficient, D′, provided by the following equation:

$${D}^{′} = {D}_{c} + \frac{{r}^{2} {V}^{2}}{48 {D}_{c}}$$

wherein D_{c} is the diffusion coefficient, r is the radius of the channel, and V is the average velocity.

Regarding FIG. 3, a concentration gradient can be measured overtime at one point in a microfluidic system producing a time-varying signal. Conversely, the concentration gradient can be measured along the length of the channel, producing a distance-varying signal. The two signals are coupled by the flow of the fluid containing the gradient along the length of the channel. The desired gradient is one that varies with defined frequency—temporal frequency and spatial frequency. Noise in a concentration gradient appears as an unintended or unexpected oscillation of the concentration. Therefore, a concentration gradient can be thought of as an oscillation in chemical concentration in which there are several contributing frequencies. Noise is the contribution of external disturbances having spectrum of temporal and spatial frequency. Frequently, noise has a higher frequency than the desired concentration gradient. When the concentration gradient is considered as a spatially varying signal, noise is, therefore, manifested as locally steep concentration gradients superposed on the desired, concentration gradient.

Specific channel geometries can facilitate diffusion and dispersion that more strongly dissipate these steeper concentration gradients—the higher spatial frequency components contributed by noise—while having only small effects on the shallower gradients—the lower spatial frequency components of the desired gradient. It is, therefore, possible to use the geometries to filter out noise associated with mechanical instabilities. For example, the “racetrack” effect caused by a fluid advancing through a curved channel can provide increased dispersion. Additionally, for example, channel expanders and reducers can provide increased dispersion. An expander is a channel section where the cross-sectional area of the channel increases in the direction of fluid flow. A reducer is a channel section where the cross-sectional area of the channel decreases in the direction of fluid flow. An expander can be followed downstream by a reducer to form an expansion channel, as described in more detail below. Additionally, outpockets of channels can increase dispersion by creating local regions where the fluid is nearly stagnant. As fluid of differing concentration flows past these outpockets, diffusion between slower moving fluid in the outpocket and the passing fluid near the center of the channel causes dispersion of concentration gradients. For example, consider the case in which fluid of low concentration moves down the channel and fills the outpockets. If a fluid of higher concentration next moves down the channel, then diffusion into the low concentration fluid in the outpocket can decrease the concentration nearer the center of the channel, decreasing the magnitude of the concentration at the center. Again, if a fluid of lower concentration now follows, diffusion out of the outpockets will elevate the concentration nearer the channel center. The total result is that oscillation in axial concentration gradients are reduced, with higher spatial frequencies being affected more strongly. These specific channel geometries can be formed at sections of a microfluidic chip, such as chip 102 shown in FIGS. 1 and 2, where it is desired to reduce steep concentration gradients. The incorporation of serpentine and expansion channels into microfluidic chips, such as chip 102, for reducing fluid flow noise is described hereinbelow.

### Serpentine Channels

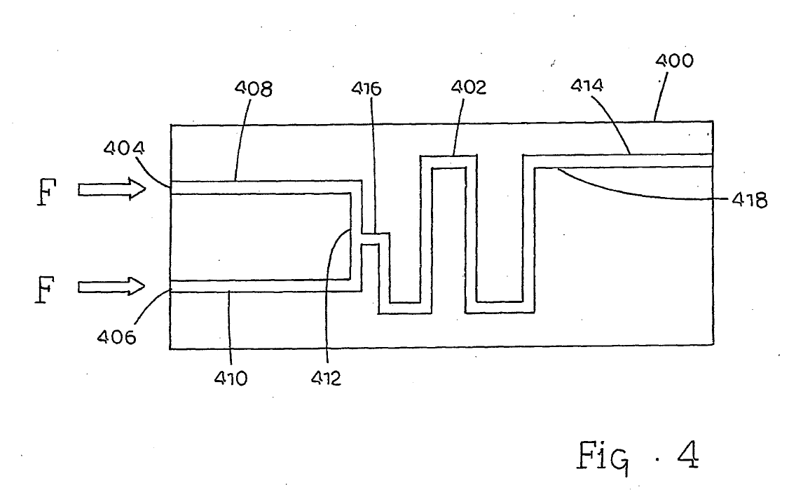

A channel including one or more curved sections, such as a serpentine channel, can be used for diffusing and dispersing locally steep concentration gradients to dissipate noise in a fluid mix concentration. As stated above, the rate of dispersion can be increased by the “racetrack” effect, which can occur as a fluid advances through a curved channel section. FIG. 4 illustrates a schematic diagram of the layout of a microfluidic chip 400 including a serpentine channel 402 for reducing noise in a concentration gradient. Microfluidic chip 400 can include two inputs 404 and 406 connected to pumps, such as pumps 104 and 106 shown in FIG. 1, for advancing fluids F through chip 400. Separate, and different if desired, fluids F can be advanced by the pumps through premixing channels 408 and 410 and combined downstream at a fluid mixing region 412. Pumps 104 and 106 can be controlled by a pump controller, such as computer 108, to combine fluids F at mixing region 412 and vary the concentration gradient of the fluids over time. Chip 400 can also include a detection channel 414 downstream from serpentine channel 402 for subjecting the mixed fluids to analysis by detection equipment.

Serpentine channel 402 can be positioned immediately downstream from mixing region 412 to disperse noise in the concentration gradient immediately after mixing. In this embodiment, serpentine channel 402 has a length of 10 centimeters and a cross-sectional area of 500 square micrometers. Alternatively, serpentine channel can have a length between approximately 0.1 and approximately 500 centimeters and a cross-sectional area between approximately 10 and 100,000 square micrometers. Serpentine channel 402 can disperse the noise generated by any type of mechanical instability, such as the noise in the fluid flow originating upstream from serpentine channel 402. Channels that are longer and have more turns can more completely decrease noise in a concentration gradient, with the noise decreasing continuously along the length of the channel.

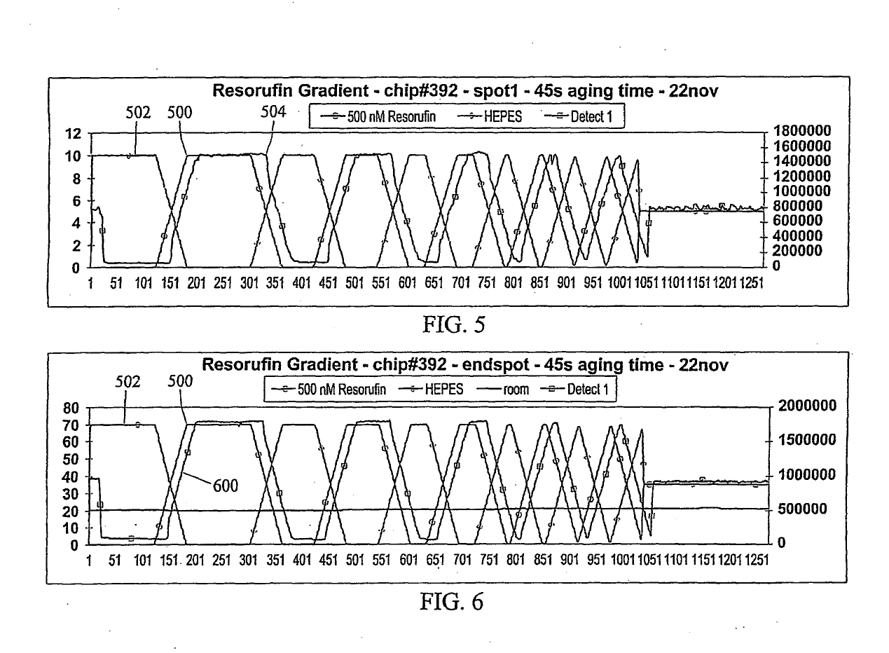

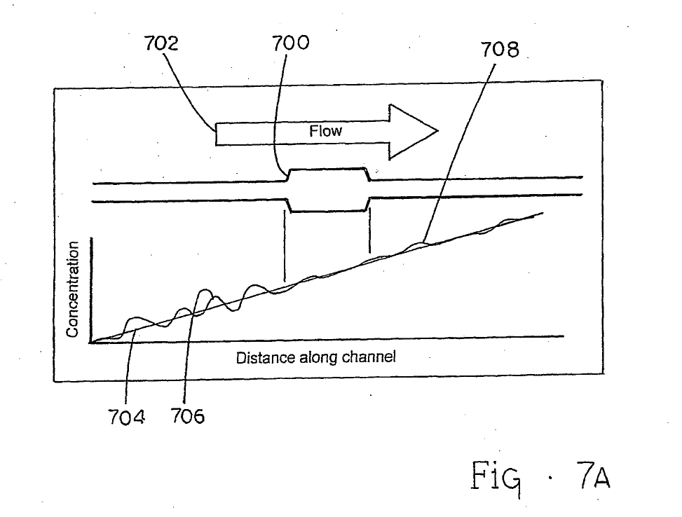

FIGS. 5 and 6 illustrate exemplary graphs of the results of running variable concentration gradients in chip 400 (shown in FIG. 4). In this example, pumps, such as pumps 104 and 106 shown in FIG. 1, advance fluorescent resorufin and a buffer, respectively, through channels 408 and 410, respectively. Graph lines 500 and 502 represent varying flow velocity profiles of fluids advanced in first and second premixing channels 408 and 410, respectively. Graph line 504 (shown in FIG. 5) represents the measurements collected just after mixing region 412 (shown in FIG. 4) at a point indicated by reference numeral 416. Referring now to FIG. 6, graph line 600 represents the measurements collected downstream from serpentine channel 402 (shown in FIG. 4) at a point indicated by reference numeral 418. By comparing the graphs shown in FIGS. 5 and 6, it can be seen that the data measured before serpentine channel 402 (shown at point 416 in FIG. 5) is noisier than the data measured after serpentine channel 402 (shown at point 418 in FIG. 6). The data measured after serpentine channel 402 is less noisy because some of the fluctuations in the concentration gradient were averaged out by dispersion through serpentine channel 402. In one embodiment, serpentine channel 402 can be connected to mixing region 412 by a connector channel having a length less than approximately 20 centimeters.

### Expansion Channels and Outpockets

As stated above, noise in the concentration of fluid mixtures can also be reduced by including an expansion channel. When fluid flows through an expansion channel, noise in the fluid flow is reduced by dispersion. Expansion channels are can be advantageous because they consume less area on a microfluidic chip, because expansion channels can better filter noise, and because expansion channels can be designed to effect different cutoff and roll-off frequencies. Dispersion can be increased by increasing the cross-sectional area of the expansion channel with respect to the channels connecting to the expansion channel, as described above in the equation for Taylor-Aris dispersion. A portion of a channel having an expansion or contraction of the cross-sectional area in the direction of fluid flow can increase dispersion.

Expansion channels can be shaped and sized for introducing a desired amount of dispersion over a predetermined spatial frequency. For example, an expansion channel acts as a low-pass filter and can be shaped and sized to possess selected cut-off frequency and decay. A channel possessing an expansion channel filter will filter only the region of the gradient that is in the filter and, thus, only the desired spatial frequency.

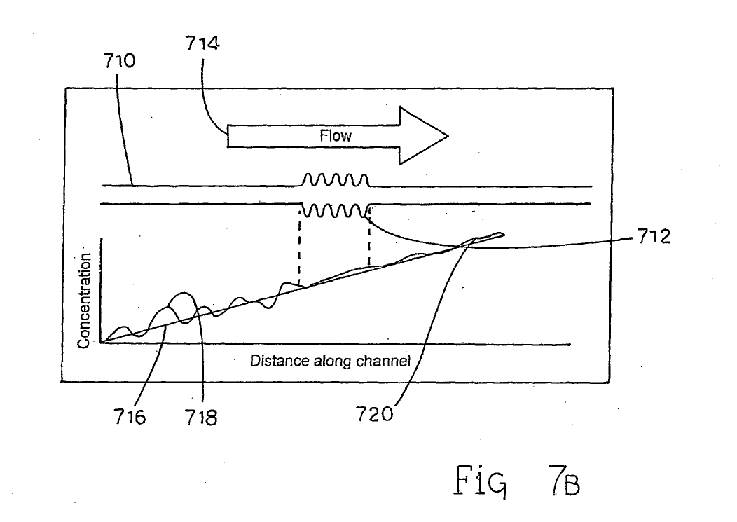

FIG. 7A illustrates a schematic diagram of an expansion channel 700 and a corresponding graph showing the concentration gradient of a fluid as the fluid advances along the length of the expansion channel. The fluid flows in a direction indicated by reference numeral 702. Graph line 704 represents a desired zero-noise gradient generated by upstream pumps, such as pumps 104 and 106 shown in FIG. 1. The zero-noise gradient has a lower spatial frequency than the filter and, thus, is only slightly affected by the filter. Graph line 706 indicates the actual gradient of the fluid as it flows through channel 700. Features with spatial frequencies approximately equal to and exceeding that of the filter are filtered out (by diffusion and dispersion), so the concentration gradient, indicated by reference numeral 708, downstream from the filter has reduced noise from higher spatial frequencies. Thus, an expansion channel can act like a low-pass filter placed into the channel to filter noise in the chemical concentration gradient, much like a low-pass filter inserted into an electrical circuit to filter out noise in the electrical signal, and similarly the expansion channel can be designed to remove specific frequencies of noise. Increasing the diameter of the expansion filter increases the strength of the filter and decreases the cutoff frequency. Increasing the length of the filter increases the strength and decreases the cutoff frequency. Channel 700 can include tapered ends to eliminate nearly stagnant flows in the corners of channel 700. The tapered ends influence the frequency roll-off of the filter.

A similar filtering effect can be introduced by placing small outpockets along the wall of the microfluidic channel. Outpockets can be considered as small expansion channels placed in series. FIG. 7B illustrates a schematic diagram of a channel 710 having plurality of outpockets 712 and a corresponding graph showing the concentration gradient of a fluid as the fluid advances along the length of the expansion channel. The fluid flows in a direction indicated by reference numeral 714. Graph line 716 represents a desired zero-noise gradient generated by upstream pumps, such as pumps 104 and 106 shown in FIG. 1. The zero-noise gradient has a lower spatial frequency than the filter and, thus, is only slightly affected by the filter. Graph line 718 indicates the actual gradient of the fluid as it flows through channel 710. Features with spatial frequencies approaching that of the filter can be filtered out (by, for example, diffusion and dispersion), such that the concentration gradient, indicated by reference numeral 720, downstream from the filter has reduced noise from higher spatial frequencies. Increasing the distance outpockets 712 extend from the axis can increase the strength of the filter and decrease the cutoff frequency. Increasing the number of outpockets 712 can increase the strength and decrease the cutoff frequency.

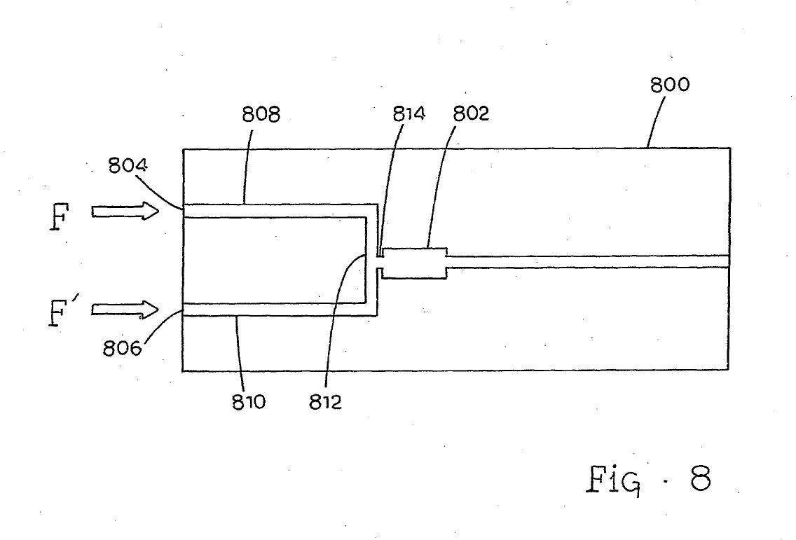

FIG. 8 illustrates a schematic diagram of the layout of a microfluidic chip 800 including an expansion channel 802 for reducing noise in a concentration gradient. Microfluidic chip 800 can include two inputs 804 and 806 connected to pumps, such as pumps 104 and 106 shown in FIG. 1, for advancing fluids F and F′, respectively, through chip 800. Separate, and different if desired, fluids F and F′ can be advanced by pumps 104 and 106, respectively, through premixing channels 808 and 810, respectively, and combined downstream at a fluid mixing region 812. Mixing region 812 can have a cross-sectional area between approximately 10 and 10,000 square micrometers. Pumps 104 and 106 can be controlled by a pump controller, such as computer 108 shown in FIG. 1, to combine the different fluids at mixing region 812 and vary the concentration gradient of the fluids over time. A connector channel 814 connects mixing region 812 to expansion channel 802. Expansion channel 802 can be positioned immediately downstream from mixing region 812 to disperse pump noise in the concentration gradient. Expansion channel 802 can have a length between approximately 0.005 and 10 millimeters and a cross-sectional area between approximately 2 and 1,000 times the cross-sectional area of connector channel 814. Microfluidic chip 800 can also include a connector channel 814 for connecting mixing region 812 to expansion channel 802. Connector channel 814 can have a length less than approximately 20 millimeters. The fluids may be laterally mixed before entering expansion channel 802, wherein lateral is defined as being perpendicular to the streamlines of the fluid flow. The placement of expansion channel 802 downstream of mixing region 812 can take into consideration the time required for lateral mixing via diffusion of components in the different fluids entering from premixing channels 808 and 810. Thus, at a given volumetric flow rate and cross-sectional area of connector channel 814, the fluid travels, for example, 20 millimeters before it is well-mixed, then expansion channel 802 should not be placed nearer than 20 millimeters to mixing region 812, i.e. connector channel 812 should be at least 20 millimeters long. Alternatively, connector channel 814 can include geometries to laterally mix the fluids by, for example, chaotic advection, or connector channel 814 can include mechanical mixers, such as magnetic beads driven laterally across connector channel 814 by an oscillating magnetic field.

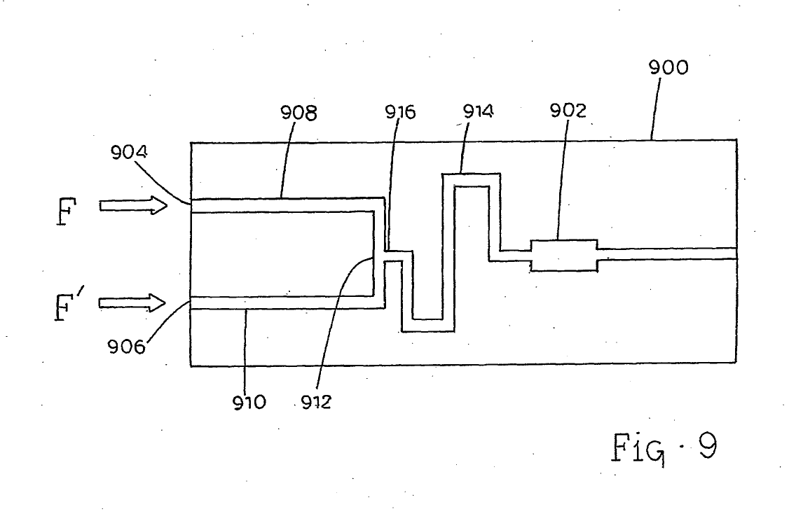

FIG. 9 illustrates another schematic diagram of the layout of a microfluidic chip 900 including an expansion channel 902 for reducing noise in a concentration gradient. Microfluidic chip 900 can include inputs 904 and 906 for connection to pumps, such as pumps 104 and 106 shown in FIG. 1, for advancing fluids F and F′, respectively, through chip 900. Separate, and different if desired, fluids F and F′ can be advanced by pumps 104 and 106, respectively, through premixing channels 908 and 910, respectively, for advancing different fluids to a mixing region 912. Expansion channel 902 can be positioned immediately downstream from a serpentine channel 914 to disperse pump noise in the concentration gradient. Serpentine channel 914 can be positioned upstream from expansion channel 902 and immediately downstream from mixing region 912 to act as a connector channel to laterally mix fluids F and F′. Thus, a serpentine channel 914 can be used to provide sufficient channel length but still fit in a compact geometry on microfluidic chip 102, to fully laterally mix the different fluids before the fluids enter expansion channel 902. Microfluidic chip 900 can also include a connector channel 916 for connecting mixing region 912 to serpentine channel 914.

Expansion channels, such as expansion channels 802 and 902 of FIGS. 8 and 9, respectively, can include certain features for achieving specific functions. For example, the expansion channels including abrupt changes in cross-sectional area tend to collect bubbles in the corners. The expansion channels can be tapered (i.e., the depth or width of the expansion channel at its ends can be changed in a gradual, continuous way) to overcome this problem. Additionally, abrupt changes in cross-sectional area introduce larger degrees of dispersion. This can cause an expansion channel to affect lower spatial frequencies more strongly—producing a more gradual roll-off of the frequency response of the expansion channel; conversely, a tapered expansion may have less dispersion and produce a sharper roll-off of the frequency response. Further, for example, the expansion channels can also be made narrow and deep for increasing the rate of mix via lateral diffusion in the expansion channel while retaining the function of being a filter.

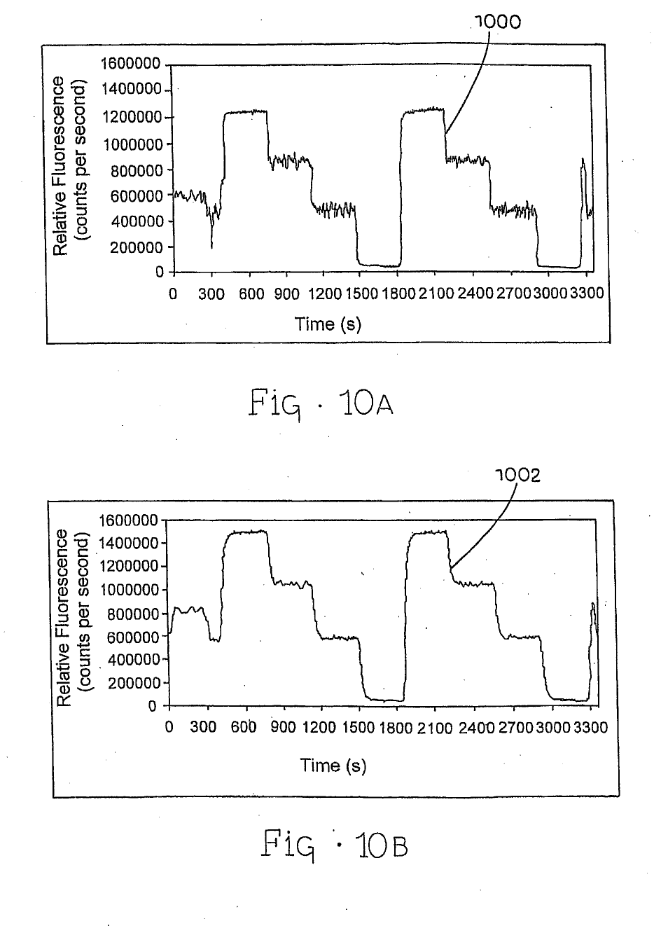

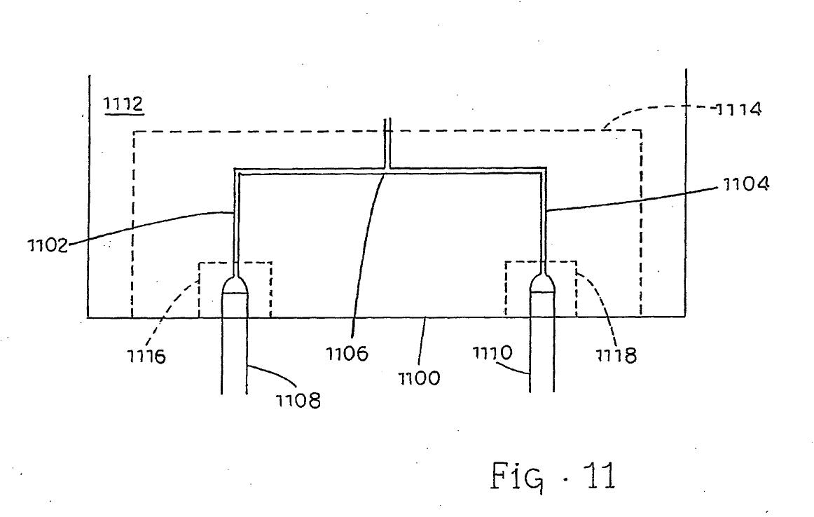

FIG. 10A illustrates an exemplary graph showing noise generated by pumps, such as first and second pumps 104 and 106 shown in FIG. 1, providing varying flow velocity profiles for fluids advanced by pumps in chip 800 (shown in FIG. 8) in a manner similar to that depicted in FIG. 3. Expansion channel 802 (shown in FIG. 8) measured 500 μm long by 300 μm wide by 100 μm deep. The fluid channel upstream and downstream of expansion channel 802 measured 25 μm wide by 15 μm deep. The combined volumetric flow rates of pumps 104 and 106 was 20 nl/min. The velocities of the pumps, and the resulting concentrations of fluorescent molecule are stepped through four steps (0:100, 33:67, 67:33, and 100:0). The flows are held constant at each step to better reveal the noise in the concentration gradient. Graph line 1000 represents the fluorescent signal measured by detection equipment immediately upstream from expansion channel 802. FIG. 10B illustrates an exemplary graph showing the fluorescent signal measured immediately downstream from expansion channel 802. As shown by graph line 1002, noise remains after flow through expansion channel 802; however, the noise is much less than that shown by graph line 1000 in FIG. 10A.

### Compliant Roof Chips

Noise in the concentration gradient of fluid mixtures can also be reduced by providing a compliant portion or other suitable flexible portion adjacent a microfluidic channel, such as channels 200 and 202 shown in FIG. 2, in a microfluidic chip, such as chip 102 shown in FIGS. 1 and 2. Examples of compliant components include a bubble in contact with the fluid, down a portion of chip 102 adjacent to the microscale channel such that the wall of the bubble behaves like a compliant membrane, and a compliant tubing between pump 104 and input channel 206. Flow velocity is proportional to pressure, so fluctuations in flow velocity also generate fluctuations in pressure. A compliant component can act like a pressure capacitor, or shock absorber, damping oscillations in pressure and, thus, flow. Such a compliant portion can function as a flexible membrane to absorb fluctuations due to mechanical instabilities, such as instabilities due to associated pumps.

For example, a microfluidic chip, such as chip 102 shown in FIGS. 1 and 2, can be formed by fabricating a channel, such as channels 200 and 202 shown in FIG. 2, or other suitable configuration into a first substrate surface and bonding a second substrate thereto to define and seal the channel. The second substrate can include a compliant portion positioned to overlay the channel formed in the first substrate when the substrates are bonded together. The compliant portion can be formed in the second substrate by thinning a portion of the substrate either prior to or subsequent to bonding. The compliant portion can be thinned to, for example, one-fourth the width of the channel beneath, such that the compliant portion acts like a thin-walled membrane. Additionally, for example, the substrate can be thinned down to less than 10 micrometers in thickness using an excimer laser or by hot embossing from a master or another technique known to those of skill in the microfabrication art. Examples of materials that can be used include any material suitable for forming the second substrate, such as polystyrene, polymethylmethacrylate, or glass, but less stiff materials can be more compliant.

FIG. 11 illustrates a schematic diagram of the layout of a portion of a microfluidic chip 1100 including flexible portions for reducing noise in the concentration gradient of fluid mixture due to mechanical instabilities. Pumps, such as pumps 104 and 106 shown in FIG. 1, can advance separated, and different if desired, fluids through channels 1102 and 1104 for mixing at a mixing junction 1106. The pumps can be fluidly connected to channels 1102 and 1104 via capillary tubes 1108 and 1110, respectively. Capillary tubes 1108 and 1110 can be attached to chip 1100 by any suitable technique, such as for example, by using an adhesive, such as epoxy.

Chip 1100 can be fabricated by forming channels 1102 and 1104 in the surface of a first substrate 1112. Next, a second substrate 1114 (shown with broken lines) including compliant portions 1116 and 1118 (shown with broken lines) can be bonded to first substrate 1112 such that compliant portions 1116 and 1118 enclose channels 1102 and 1104, respectively. Compliant portions 1116 and 1118 can absorb fluctuations in flow rates of fluids advanced by the pumps into channels 1102 and 1104, respectively.

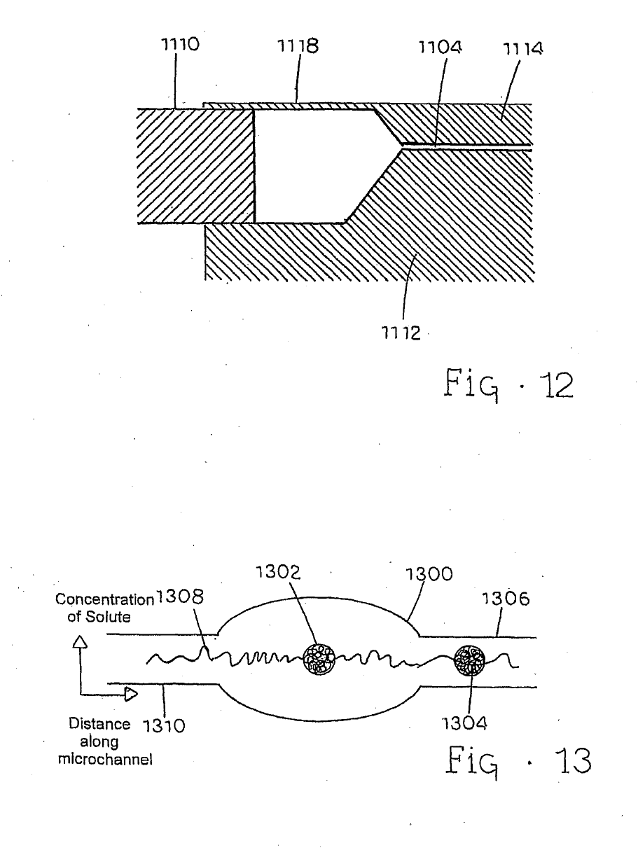

FIG. 12 illustrates a cross-sectional view of channel 1104 of microfluidic chip 1100. As shown, compliant portion 1118 is thin for absorbing fluctuations in the flow rates of fluids advanced out of capillary tube 1110 into channel 1104.

### Detection Channels

Noise in the measurement of a concentration gradient of fluid mixtures can also be reduced by increasing the spatial dimension of the detection region spanned by the detector that measures the chemical concentration, such as fluorescence detection system 110, shown in FIG. 1. Once the spatial dimension of the detector matches the spatial frequency of the major components of noise in the chemical concentration gradient such that the detector measures over one or more oscillations of the noise, then the detector can effectively integrate over the noise and decrease its effect. This is only possible if the spatial dimension of the detector is equal to or larger than the spatial dimension of the noise in the chemical concentration gradient. There are two ways the spatial dimension of the detector can be increased relative to the spatial dimension of the noise in the chemical concentration gradient: (1) the axial length along the channel measured by the detector can be increased by using either a larger detector or, for optical systems, by using appropriate optics to focus a longer segment of the channel onto the detector; and (2) an expansion channel can be placed at the point of detector. This second approach causes oscillations in the gradient to be “squeezed together” due to continuity of flow, e.g., as the channel widens, the axial distance between fluid regions shortens. When fluid flows through an expansion channel, the linear velocity of the fluid decreases. When fluorescent product is detected at an expansion channel, the detection spot can then encompass more of the deviations in concentration generated by the noise and average them out.

Referring to FIG. 13, an expansion channel 1300 of a microfluidic chip, such as chip 102 shown in FIG. 1, includes areas illuminated by two laser spots 1302 and 1304. Laser spot 1302 is focused on expansion channel 1300 and fluorescence from this spot is detected by detection equipment 110, shown in FIG. 1. Laser spot 1304 is focused downstream of the expansion channel in channel segment 1306. Line 1308 represents the concentration of a solute in a fluid advanced through expansion channel 1300, illustrating how the spatial frequency of noise in the concentration gradient increases in the expansion channel 1300. Laser spot 1302 spans several oscillations in the concentration of the solute and will, therefore, average out these higher spatial frequencies. Conversely, laser spot 1304 spans one or fewer oscillations in the concentration of the solute.

An additional advantage of an expansion channel at the detection point can be realized if the channel is deeper than the upstream fluidic channel. The deeper channel places the laser spot further from the material of which the microfluidic chip is fabricated. Frequently these materials autofluoresce, contributing to the measured background signal. Moving the laser spot further from this material decreases autofluorescence and maximizes fluorescence from the sample of interest, boosting signal-to-background noise.

Similarly, other detection schemes can benefit from these approaches, for example, absorption spectroscopy in which the axial length of the channel is the path length of the absorption cell will average out noise if the axial length of the channel is greater than the spatial scale of the noise, and electrochemical detection in which the electrodes span longer axial distances can similarly average out noise. In this embodiment, laser spot 1302 can extend a distance, in the direction of the channel length, between approximately 0.1 to 10 times the diameter of expansion channel 1300. Expansion channel 1300 can be connected to channels 1306 and 1310 for advancing fluid through expansion channel 1300. Expansion channel 1300 can have a cross-sectional area between approximately 2 and 500 times the cross-sectional area of channels 1306 and 1310. Additionally, expansion channel 1300 can have a length between approximately 0.005 and 10 millimeters. Additionally, channel 1306 is not needed if the fluid is not being conveyed downstream for further processing.

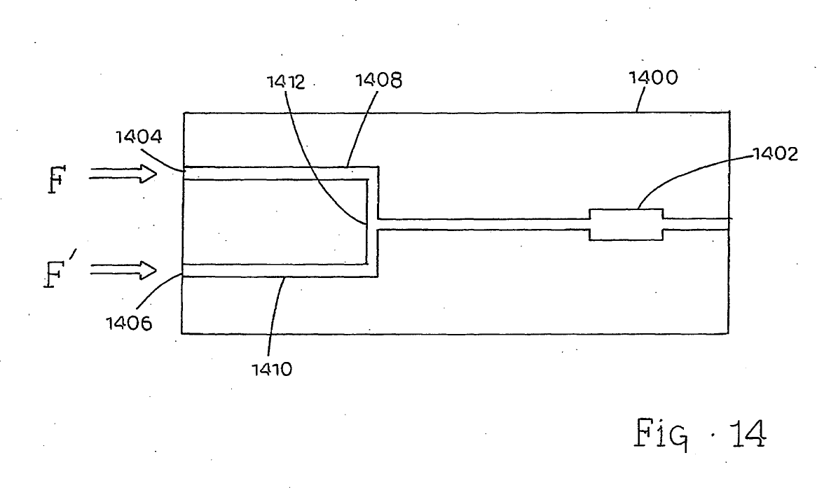

FIG. 14 illustrates a schematic diagram of the layout of an exemplary microfluidic chip 1400 including an expansion channel 1402 for detecting a fluorophore product. The dimensions of the expansion channel 1402 depend on the spatial frequency of the noise. The distance decreases between peaks in the oscillations of chemical concentration gradient 1308 as illustrated in FIG. 13 as either or both the width or depth of the channel increases. Microfluidic chip 1400 can include inputs 1404 and 1406 for connection to pumps, such as pumps 104 and 106 shown in FIG. 1, for advancing fluids F and F′, respectively, through chip 1400. Separate, and different if desired, fluids can be advanced by pumps 104 and 106 through premixing channels 1408 and 1410, respectively, for advancing different fluids to a mixing region 1412. Expansion channel 1402 can be positioned a distance downstream from mixing region 1412. Detection equipment, such as detection equipment 110 shown in FIG. 1, can be positioned and configured to detect fluorophore product in expansion channel 1402.

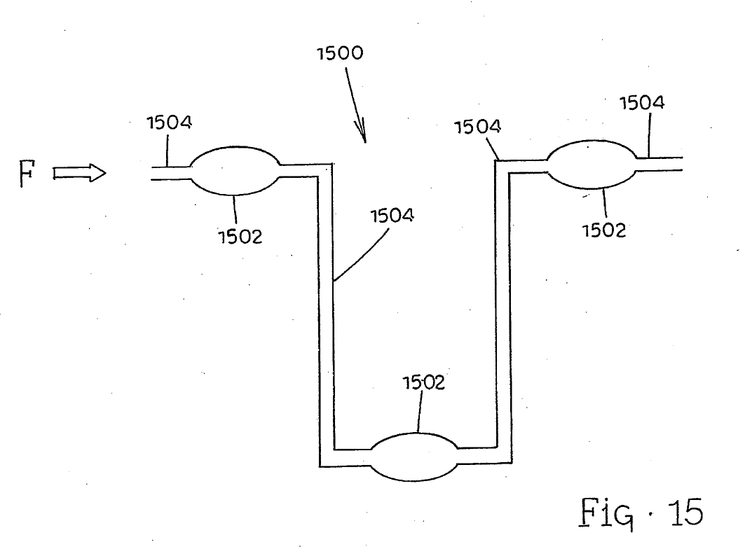

FIG. 15 illustrates a schematic diagram of the layout of a detection portion, generally designated 1500, of a microfluidic chip, such as chip 102 shown in FIG. 1. Detection portion 1500 includes a plurality of expansion channels 1502 where fluorophore product can be measured at detection spots by detection equipment, such as detection equipment 110 shown in FIG. 1. Detection channels can be connected via a plurality of channels 1504 which can be narrower than expansion channels 1502. Fluid F can flow in a direction through detection portion 1500 as indicated by the arrow. The detection portions 1500 can be positioned downstream from a mixing junction. If multiple detectors are placed at expansion channels 1502, or if one detector is moved between expansion channels 1502, then multiple points on channel 1504 can be measured, permitting measurement of multiple times after mixing of a concentration gradient. The size and geometry of expansion channels 1502 and channels 1504 can vary from one another according to different embodiments.

### Data Processing Methods

A computer, such as computer 108 shown in FIG. 1, can include hardware/software for filtering the noise in the signals measured by detection equipment, such as detection channel 216 shown in FIG. 2. For example, the detection equipment can receive and convert the chemical signal detected at the detection channel to an electrical signal for transmission to the computer. Typically, the electrical signal is an analog signal and can be converted to a digital signal for processing by the computer. The computer can include instructions stored on a computer-readable medium for executing algorithms for filtering noise in the received signals.

The noise due to mechanical instabilities can be reduced by filtering certain frequencies corresponding to noise generated by mechanical instabilities. Typically, frequencies higher than 0.1 Hz are filtered. The algorithms implemented by the computer can filter the noise using averaging, such as weighted averaging or more specifically designed digital filters, such as a Butterworth filter. In one embodiment, the Butterworth filter or other filter known to one of skill in the art has a cutoff frequency of approximately 0.5 Hertz.

The detection equipment, such as detection equipment 110 shown in FIG. 1, can also include hardware/software components for filtering noise in the electrical signal. For example, the signal can be filtered with analog filtering hardware, such as a capacitor or other electronic filters known to those of skill in the art.

### Tracer Dyes

A microfluidic system, such as system 100 shown in FIG. 1, can introduce a tracer dye into the fluids advanced through a microfluidic chip, such as chip 102 shown in FIGS. 1 and 2, for reducing noise due to mechanical instabilities. Tracer dyes can be applied to an experiment which mixes continuous concentration gradients, as described above, through any of the above described chips. In fluorescence, the tracer dye emits light at a wavelength distant from that of any signal of interest, permitting the concentration of the tracer dye to be measured independently of any signal fluorescence. If a tracer dye is added to one of the pumps, such as pumps 104 and 106 shown in FIG. 1, the concentration of the tracer dye in a downstream, post-mix flow reports the ratio of the mix. In a noisy concentration gradient, a tracer dye can, therefore, be used to measure the inaccuracies in the mix and, thereby, be used by a computer, such as computer 108 shown in FIG. 1, to remove the noise.

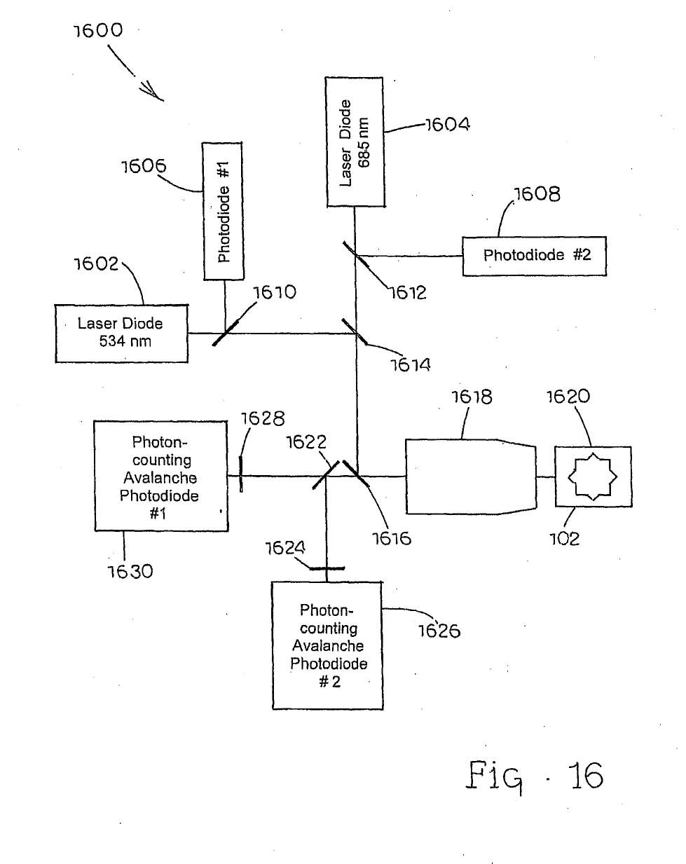

Referring to FIG. 16, a schematic diagram of a microfluidic system 1600 for measuring both a product fluorophore and a tracer dye is illustrated. In this example, the tracer dye can excite and emit at wavelengths longer than the reaction product fluorophore. In one example, resorufin can be the reaction product and Alexa 700 (available from Molecular Probes, Inc. of Eugene, Oreg., U.S.A.) can be the tracer dye fluorophore. Two lasers 1602 and 1604 can be used as excitation sources. Laser 1602 can be a shorter wavelength laser (e.g., a green, 534 nm, Helium-Neon laser, provided by Coherent, Inc. of Santa Clara, Calif. or a frequency doubled DPSS laser emitting at 532 nm, provided by StockerYale Inc. of Salem, N.H.) used to excite resorufin. Laser 1604 can be a longer wavelength laser (e.g., a 685 nanometer laser diode, provided by StockerYale Inc) used to excite Alexa 700. The output of both lasers 1602 and 1604 can be measured by reflecting a small fraction of the light from the laser with a 2% beamsplitter 1610 and 1612 to photodiodes 1606 and 1608 for correcting variation of laser intensity. The two beams are combined with a dichroic beamsplitter 1614 having a cutoff wavelength between the wavelengths of lasers 1602 and 1604. The combined beams can then be reflected by a multipass dichroic beamsplitter 1616 (e.g., a 543-687 pc Lot 102132 beamsplitter available from Chroma Technology Corp. of Rockingham, Vt.) to a microscope objective 1618. Beamsplitter 1616 can be selected such that it reflects the light from lasers 1602 and 1604 and transmits the light from the two fluorophores—the fluorescent product and the tracer dye. In one embodiment, beamsplitter 1616 can be matched to lasers 1602 and 1604 and transmission bands matched to the fluorescent product and tracer dye.

The combined laser beams are brought to focus inside microfluidic channel 1620 of a microfluidic chip 102 where the fluorescent product and the tracer dye are excited and thereby emit fluorescent light that is collected by microscope objective 1618. Objective 1618 can be a high numerical aperture objective for delivering an excitation beam to the sample and capturing fluorescence emitted by the sample. The fluorescent light transmits through dichroic beamsplitter 1616 and travels to a second dichroic beamsplitter 1622 which achieves the following: (a) reflects the shorter wavelength fluorescent light from the fluorescent product through barrier filter 1624 to avalanche photodiode 1626, or other suitable light detector known to those of skill in the art; and (b) transmits the longer wavelength fluorescent light from the tracer dye through barrier filter 1628 to avalanche photodiode 1630, or other suitable light detector known to those of skill in the art. Beamsplitter 1622 can have a cutoff wavelength between the wavelengths of light emitted from the fluorescent product and the tracer dye. Avalanche photodiodes 1626 and 1630 can measure the fluorescent light and transmit signals to a noise normalizer, such as computer 108, shown in FIG. 1, which is operable to normalize noise in the fluorophore product signal based on noise detected in the tracer dye signal. Noise can be normalized by using the concentration of the tracer dye to remove noise from measurements of the fluorescent product produced by the biological response or biochemical reaction. Avalanche photodiodes 1626 and 1630 can be operable to count single photons. For additional accuracy, oscillations of the fluorescence of the two dyes arising from oscillations in beam intensity from lasers 1602 and 1604 can be corrected by measuring the output of the lasers with photodiodes 1606 and 1608. As known to those of skill in the art, the substitution of filters and/or lasers can permit the use of other fluorophores, dual fluorescence detection can permit other techniques, such as ratio fluorometry; and substitution of continuous-wave lasers with pulsed lasers can permit time-resolved fluorescence measurements. Additionally, more than two lasers can be combined with such techniques to permit multiple-wavelength configuration of microfluidic system 1600.

Appropriately sized quantum dot structures can also be used to replace fluorescent dyes. Two or more types of quantum dots can be used that utilize the same excitation source, but emit at different wavelengths. In this case, the optical system of FIG. 16 can be simplified by removing laser source 1604 and associated beam splitter 1612 and detector 1608.

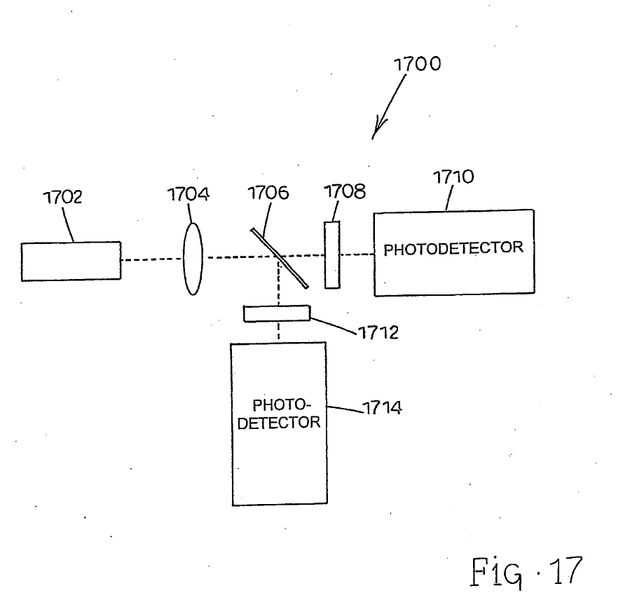

Detection of multiple fluorescent dyes requires excitation by a multi-laser system, such as in FIG. 16, requires an optical system capable of discriminating the different wavelengths of light emitted by the different fluorescent dyes. FIG. 17 illustrates an optical system 1700 for measuring light emitted by both a product fluorophore and a fluorescent tracer dye. Fluorescent light from the reaction emits from optical port 1702 and is relayed by lens system 1704. This light is then split into a beam of short wavelength light and a beam of long wavelength light by beamsplitter 1706. The long wavelength light is then filtered by optical filter 1708 and then measured by photodetector 1710. Similarly, the beam of shorter wavelength light is then filtered by optical filter 1712 and then measured by photodetector 1714. Appropriate selection of wavelength-selective components, beamsplitter 1706 and optical filter 1708 and 1712 allows configuration of the system for different fluorescent dye pairs. Multiple lenses can comprise lens system 1704 permitting appropriate design of magnification of the image of the fluorescent spot onto photodetectors 1710 and 1714. Additionally, the axial positions of photodetectors 1710 and 1714 can be adjusted to position the face of the photodetector on the focused image of the fluorescent spot relayed by lens system 1704. If the photodetectors are spot detectors, like an avalanche photodiode model SPCM-AQR (available from PerkinElmer, Inc. of Wellesley, Me., U.S.A.), then this system can behave like a confocal imaging system, rejecting out-of-focus fluorescence.

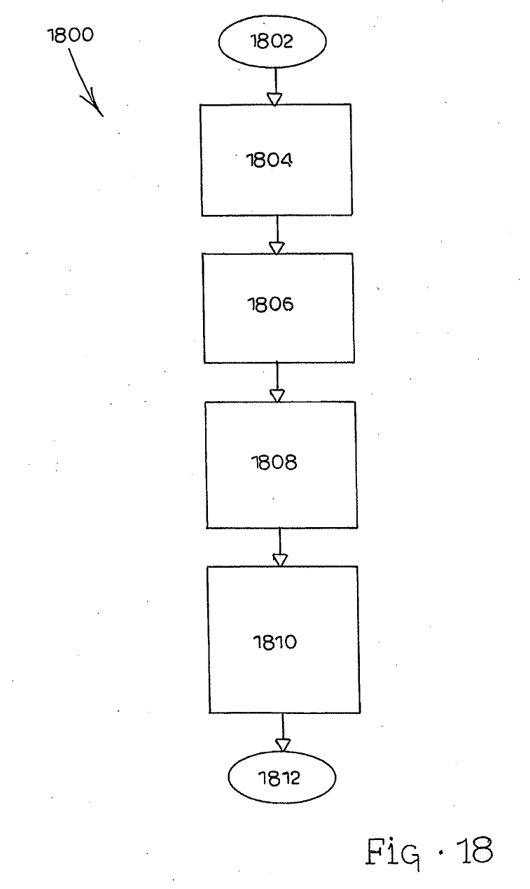

Referring to FIG. 18, a flow chart, generally designated 1800, is provided to illustrate an exemplary process for reducing concentration gradient noise in a microfluidic system, such as system 100 shown in FIG. 1, by adding tracer dye to the fluids. Tracer dye needs only be added to one of the fluids if the flow of that fluid can be varied from 0% to 100% to permit calibration of the full range of fluorescence of that dye. Thus, minimal fluorescence would indicate 0% flow of that fluid (and 100% flow of the counter-fluid), maximal fluorescence would indicate 100% flow of that fluid (and 0% flow of the counter-fluid), and intermediate fluorescence would relate linearly to the proportional flow rate of that fluid in generating the gradient.

The process begins at start step 1802. In step 1804, pumps, such as pumps 104 and 106 shown in FIG. 1, can be loaded with fluids, such as the reagents for a reaction to be measured. The fluid in, for example, pump 104 can contain a predetermined amount of tracer dye.

Next, at step 1806, the pumps can be controlled to advance the fluids into and through a microfluidic chip, such as chip 102 shown in FIGS. 1 and 2, for mixing at a mixing junction, such as mixing junction 210 shown in FIG. 2.

Next, at step 1808, the fluids can then be advanced to a detection channel, such as detection channel 216 shown in FIG. 2, for detection of the tracer dye and fluorophore product. Detection equipment, such as detection equipment 110 shown in FIG. 1, can detect the tracer dye at detection channel 216 and transmit a representative signal of the tracer dye and product to a computer, such as computer 108 shown in FIG. 1.

Next, at step 1810, the computer can directly measure the ratio of the mix of the two fluids based on the signal representing the tracer dye. Thus, 40% of (maximal fluorescence minus minimum fluorescence) would indicate that flow from pump 104 is 40% of the total, and components from that pump are at 40% maximal while components from pump 106 are at 60% maximal. Thus, by directly measuring the ratio of the mix, the concentration of the reagents is also known. Next, the process can stop at step 1812.

It may be desirable to measure the extent of reaction by measuring the production of a fluorogenic product, i.e., the reaction produces a fluorescent signal proportional to the product of the reaction. This is common in biochemical assays in which a non-fluorescent reagent is converted to a fluorescent product by the action of an enzyme, frequently as part of a coupling system for monitoring the reaction of another enzyme. For example, AMPLEX® Red (available from Molecular Probes, Inc. of Eugene, Oreg.) is converted to highly fluorescent resorufin. In this case, a fluorescent tracer dye can be used, but the fluorescent signal from the product must be distinguishable from the fluorescent signal from the tracer dye. This can be done by using a tracer dye that has absorption and/or emission spectra that are different from the fluorescent product.

One embodiment uses one fluorescent dye (e.g., ALEXA FLUOR® 700 available from Molecular Probes) as a tracer dye to measure the ratio of the mixture generated by two pumps, and a second fluorescent dye (e.g., resorufin) is the product of a fluorogenic reaction of other components in the fluids (e.g., a biochemical reaction) being measured with the instrument. Alexa 700 is thus a passive tracer dye, while resorufin reports the extent of reaction. In the course of the experiment, the concentration gradient is created by pumps 104 and 106 which vary from 0% to 100% of some flow rate (e.g., 20 nl/min).

An instrument such as depicted in FIG. 1 is used, in which light source 112 is the dual laser system depicted in system 1600 shown in FIG. 16 and light detector 114 is system 1700 shown in FIG. 17. Thus, two different wavelength laser beams are transmitted to the fluid in the microfluidic channel, and light emitted by the two fluorescent dyes is transmitted to two light detectors 1710 and 1714 as shown in FIG. 17.

The signals measured by two photodetectors 1710 and 1714 can be corrected for background light (e.g., autofluorescence) from the substrate into which the channels are made, or fluorescence from a non-reactive component in the fluids) and for bleedthrough of light from one fluorescent dye into the light path measured by the other detector. It is common for fluorescent dyes to emit with broad shoulders extending into longer wavelengths. Thus, these dyes will emit light that is transmitted to the detector for the dye that emits at the longer wavelength. Additionally, photodetectors have different sensitivities to different wavelengths of light, and the responses of the photodetectors is frequently non-linear with respect to light intensity. The signals from the photodetectors must be corrected for this differential sensitivity and non-linearity.

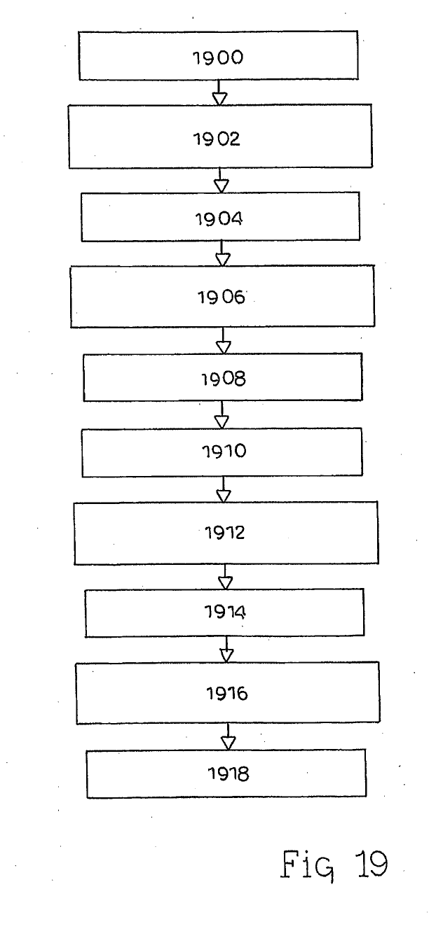

FIG. 19 illustrates a flow chart of an exemplary process for correcting signals from two photodetectors. In this exemplary process, the photodetectors can be avalanche photodiodes (APD1 and APD2) (model SPCM-AQR) available from PerkinElmer, Inc. of Wellesley, Me., U.S.A.). At step 1900, fluid containing no fluorophore can be run through the channels to measure background fluorescence, where c₁ (concentration of fluorophore 1 in moles/liter) and c₂ (concentration of fluorophore 2 in moles/liter) are set to 0. Next, at step 1902, APD1 background b₁ (in counts per second) can be determined with the equation b₁=S₁/(1−S₁d), where S₁ is the raw output from APD1 in counts per second and d is the “dead time” for the APD1 and APD2. At step 1904, APD2 background b₂ (in counts per second) can be determined with the equation b₂=S₂/(1−S₂d), where S₂ is the raw output from APD2 in counts per second.

At step 1906, a fluid containing one fluorescent dye at a predetermined concentration c₁ is run and c₂ is set to 0. g₁₁ (the calibration coefficient in (counts/second)/mole) can be determined with equation g₁₁=[S₁/(1−S₁d)−b₁]/c₁ (step 1908). g₂₁ (the calibration coefficient in (counts/second)/mole) can be determined with equation g₂₁=[S₂/(1−S₂d)−b₂]/c₁ (step 1910).

At step 1912, a fluid containing another fluorescent dye at predetermined concentration c₂ is run and c₁ is set to 0. g₁₂ (the calibration coefficient in (counts/second)/mole) is determined with equation g₁₂=[S₁/(1−S₁d)−b₁]/c₂ (step 1914). g₂₂ (the calibration coefficient in (counts/second)/mole) is determined with equation g₂₂=[S₂/(1−S₂d)−b₂]/c₂ (step 1916). The photodiodes are set with calibrations coefficients g₁₁, g₁₂, g₁₂, and g₂₂ (step 1918).

The above equations are based on the following equations for S₁ and S₂.

$$\begin{matrix}{S}_{1} = \frac{{c}_{1} {g}_{11} + {c}_{2} {g}_{12} + {b}_{1}}{1 + d ( {c}_{1} {g}_{11} + {c}_{2} {g}_{12} + {b}_{1} )} \\ {S}_{2} = \frac{{c}_{1} {g}_{21} + {c}_{2} {g}_{22} + {b}_{2}}{1 + d ( {c}_{1} {g}_{21} + {c}_{2} {g}_{22} + {b}_{2} )}\end{matrix}$$

c₁ and c₂ can be determined from subsequent measurements of S₁ and S₂ during an experiment and simultaneous solution of the above two equations for c₁ and c₂.

The counts per second measured by the avalanche photodiodes for the background and for the predetermined concentrations of the dyes can be used to calculate calibration coefficients. These calibration coefficients can then be used to correct all subsequent measurements made with this optical system for these fluorescent dyes.

### Mixing More than Two Fluids

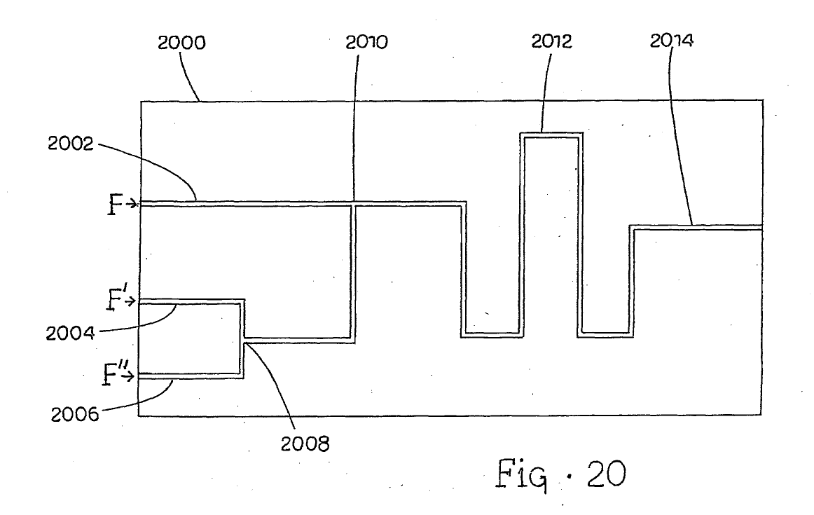

Referring to FIG. 20, a schematic diagram of an exemplary embodiment of a microfluidic chip, generally designated 2000, including channels 2002, 2004, and 2006 for introducing fluids F, F″, and F′″, respectively. Fluids F′ and F″ mix at a first junction 2008. The flows of fluids F′ and F″ are controlled to produce linear concentration gradients, such as depicted in FIG. 3, with the combined volumetric flow rates of flows F′ and F″ equaling a constant. The mixed fluids F′ and F″ can then be mixed with fluid F at a second junction 2010. Here the flow rates of fluid F, F′, and F″ are constant, and the gradient generated at first junction 2008 persists as the fluid flows down serpentine channel 2012 to a detection point 2014 where the chemical concentration is measured.

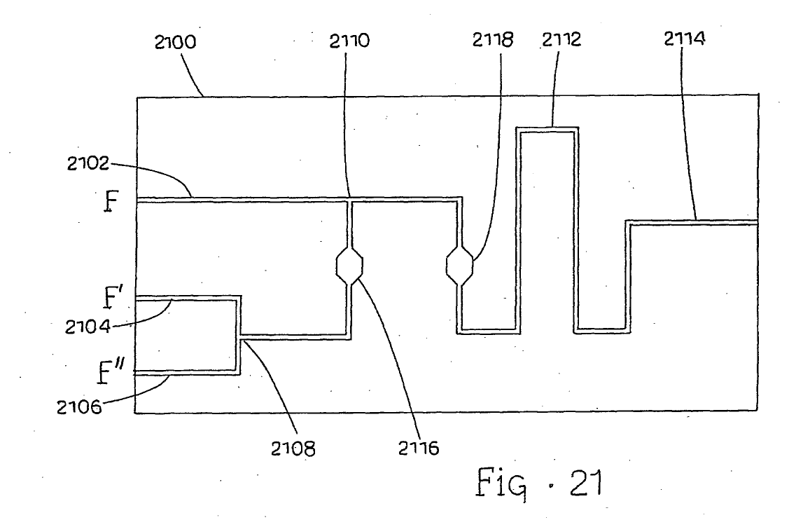

Noise introduced independently by the fluid flows of fluid F, F′, and F″ can be reduced by the introduction of multiple expansion channels or regions with small outpockets along the wall of the microfluidic channel. Referring to FIG. 21, a schematic diagram of an exemplary embodiment of a microfluidic chip, generally designated 2100, including channels 2102, 2104, and 2106 for introducing fluids F, F″, and F′″, respectively. Microfluidic chip 2100 also includes a first mixing junction 2108, a second mixing junction 2110, a serpentine channel 2112, and output channel 2114 similar to microfluidic chip 2000 shown in FIG. 20. In addition, microfluidic chip 2100 can include expansion channels 2116 and 2118. Expansion channel 2116 is positioned between junctions 2108 and 2110 to remove noise from the mix of fluids F′ and F″. Expansion channel 2118 can then be placed downstream of junction 2110 to filter noise from the gradient introduced at junction 2110 by the flow of fluid F.

### Controlling Adsorption Effects

Adsorption of a molecule to the wall of a microfluidic channel can sometimes present a problem in microfluidic and other miniaturized systems in which the ratio of surface area to volume is many orders of magnitude larger than is found in more conventional approaches, such as for example, dispensing and mixing of solutions in microtiter plates. Adsorption of molecules in microfluidic systems and other miniaturized devices can be a major obstacle to miniaturization as the adsorption can affect molecule concentrations within fluids, thereby negatively impacting data collected from the microfluidic systems or other miniaturized devices. Adsorption driven changes in concentration can be especially problematic for microfluidic systems used to generate concentration gradients.

In some embodiments, the presently disclosed subject matter provides apparatuses and methods for using the same that can decrease the interference of adsorption to concentration dependent measurements, such as in biochemistry reactions including IC₅₀ determinations, by altering the geometry of a microfluidic channel. Although adsorption may not be eliminated, the change in concentration caused by adsorption can be minimized. In general terms, the effects of adsorption on measurements can be minimized by reducing the ratio of channel surface area to fluid volume within the channel (S/V), which also increases diffusion distances. However, as a high surface area to volume ratio can be an unavoidable consequence of the miniaturization of microfluidics, the geometries provided by some embodiments of the presently disclosed subject matter to minimize adsorption consequences are most unexpected by persons in the field of microfluidics. The presently disclosed subject matter provides for, in some embodiments, using large channel diameters in regions of the microfluidic chip most affected by adsorption of reaction components, that is, in regions where a reaction proceeds and/or where measurements are taken. In some embodiments of the presently disclosed subject matter, and with reference to the microfluidic chip embodiment shown in FIG. 2, large channel diameters at a detection point of detection channel 216 can be provided to reduce adsorption effects, as a substitute for or in combination with serpentine channel 214 (also referred to as aging loop).

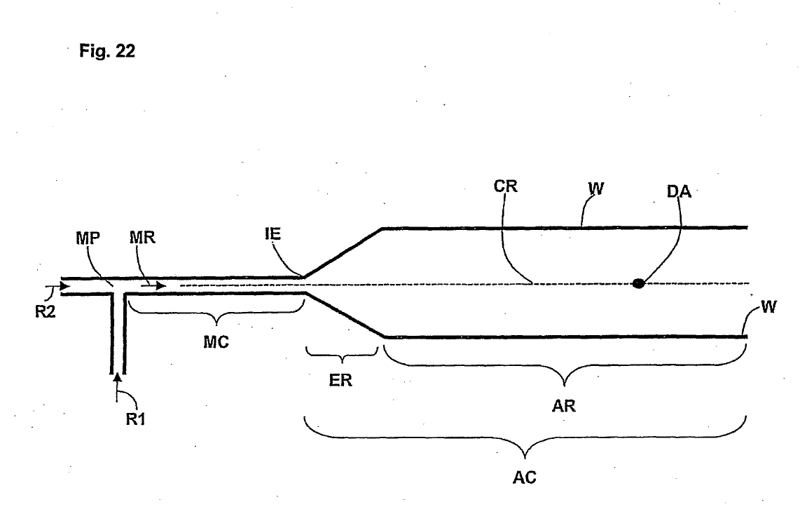

Turning now to FIG. 22, an embodiment of a novel analysis channel of the presently disclosed subject matter is illustrated in a top view. FIG. 22 shows the direction of flow by arrows R1 and R2 of two fluid reagent streams, which can combine at a merge region or mixing point MP. After combining into a merged fluid stream, the reagents within the stream can flow in a direction indicated by arrow MR down a mixing channel MC that can be narrow to permit rapid diffusional mixing of the reagent streams, thereby creating a merged fluid reagent stream. The fluid stream of reagents can then pass into an analysis channel AC, at an inlet or inlet end IE that can have a channel diameter and a cross-sectional area equivalent to that of mixing channel MC. The merged fluid stream can then flow through an expansion region ER that can have a cross-sectional area that can gradually increase and where the surface area to volume ratio can thereby gradually decrease. The merged fluid stream can then continue into an analysis region AR of analysis channel AC with an enlarged cross-sectional area and a reduced surface area to volume ratio. A reaction can be initiated by mixing of the reagent streams at the mixing point MP. However, due to continuity of flow, the flow velocity slows dramatically in analysis region AR of analysis channel AC, and the majority of transit time between mixing point MP and a detection area DA is spent in the larger diameter analysis region AR. Measurements can be made inside this channel, such as with confocal optics, to achieve measurements at detection area DA, which can be located at a center axis CR of analysis region AR of analysis channel AC. Center analysis region CR can be a region equidistant from any channel wall W of analysis channel AC. Thus, the fluid at center analysis region CR of detection area DA can be effectively “insulated” from adsorption at channel walls W. That is, the amount of any reagents removed at channel wall W can be too small, due to the greatly decreased surface area, and the diffusion distance to channel wall W can be too long, due to the greatly increased diffusion distance from center analysis region CR to channel wall W, to greatly affect the concentration at centerline CL. The confocal optics, for example, can reject signal from nearer channel wall W of analysis region AR, permitting measurements to be made at center analysis region CR where the concentration is least affected by adsorption at channel wall W.

A consequence of increasing analysis channel AC cross-section by increasing channel diameter is that the ratio of channel surface area to fluid volume (S/V) within the channel is decreased, relative to a narrower channel. For example, to measure a reaction 3 minutes after mixing, with a volumetric flow rate of 30 nL/min, the reaction should be measured at a point in the channel such that a microfluidic channel section spanning from mixing point MP to detection area DA encloses 90 nL. For an analysis channel with a square cross-section and a diameter of 25 μm, this point is about 144 mm downstream from mix point MP. This channel has a surface area of 1.44×10⁻⁵ square meters, yielding a surface to volume ratio S/V equal to 1.6×10⁵ m⁻¹. For a channel with a diameter of 250 μm, the measurement is made 1.44 mm downstream from mix point MP. This wider channel has a surface area of 1.44×10⁻⁶ square meters, yielding a S/V equal to 1.6×10⁴ m⁻¹, which is 1/10^{th} the S/V of the narrower channel. This alone can decrease ten-fold the removal of compound per unit volume by adsorption.

This geometry change can also decrease the radial diffusive flux of compound. Flow in these small channels is at low Reynolds number, so diffusion from a point in the fluid is the only mechanism by which compound concentration changes radially in a microfluidic channel. Increasing the radius of the channel, thereby decreasing the radial diffusive flux, therefore, means that the concentration of compound at center analysis region CR of analysis region AR can be less affected by adsorption than in the smaller upstream channels.

Thus, increasing the cross-sectional area of analysis region AR of analysis channel AC can both decrease the amount of adsorption at the wall per unit volume and decrease the rate of flux of compound from center analysis region CR to any of channel walls W. Both together mean that the concentration at center analysis region CR can decrease more slowly due to adsorption of compound.

Further, in all embodiments, the surface area of all channels exposed to compounds, not just analysis channel AC, can preferably be kept minimal, especially those channels through which concentration gradients flow. This can be accomplished by making channels as short as practicable. Additionally, when the volume contained by a channel must be defined (e.g. where the channel must contain a volume of 50 nL), it is best to use larger diameters/shorter lengths wherever possible to reduce S/V.

Another benefit of increasing analysis channel AC cross-section by increasing channel diameter is that the length of the channel down which the fluid flows can be reduced. In the example given earlier, a channel with 25 μm diameter needed to be 144 mm long to enclose 90 nl whereas the channel with 250 μm diameter needed to be only 1.44 mm long. This shorter channel can be much easier to fabricate and has a much smaller footprint on a microfluidic chip.

Still another benefit of increasing analysis channel AC cross-section is that it will behave like an expansion channel, which filters noise out of chemical concentration gradients, as described herein. The result is that signal to noise is larger in an analysis channel AC with larger cross-section.

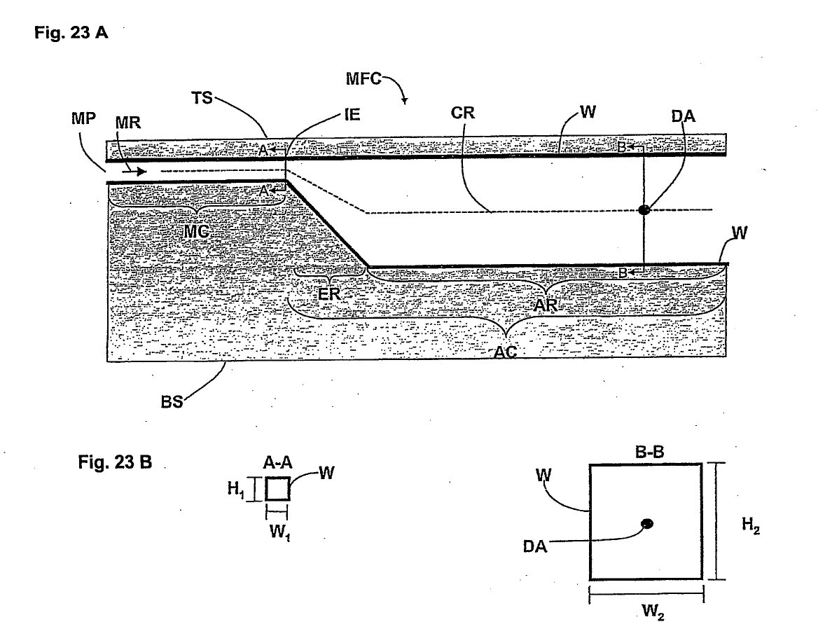

FIG. 23A presents a cross-sectional side view of a portion of a microfluidic chip MFC comprising mixing channel MC and analysis channel AC depicted in FIG. 22. Microfluidic chip MFC shown in FIG. 23A can be constructed by machining channels into a bottom substrate BS and enclosing channels by bonding a top substrate TS to bottom substrate BS or otherwise forming channels within microfluidic chip MC with bottom substrate BS and top substrate TS being integral. In FIG. 23A, only the flow of merged reagent fluid stream having a flow direction indicated by arrow MR after mixing point MP is shown. Flow in a microfluidic channel can be at low Reynolds number, so the streamline of fluid that flows along center analysis region CR of the narrower mixing channel MC can travel at the mid-depth along entire mixing channel MC, becoming center analysis region CR of analysis region AR of analysis channel AC. Detection area DA can reside along center analysis region CR at a point sufficiently far downstream of mixing channel MC to permit the reaction to proceed to a desired degree.

Analysis channel AC can approximate a circular cross-section as closely as possible to produce the smallest ratio of surface area to volume, and also to produce the largest diffusion distance from centerline center analysis region CR to a channel wall W. However, microfluidic channels may not be circular in cross-section due to preferred manufacturing techniques. Rather, they can be more likely square in cross-section, with the exact shape depending on the technique used to form the channels. For such channels, a cross-section of analysis channel AC, particularly within analysis region AR, can have an aspect ratio as close to one as possible or, more precisely stated, the distance from center analysis region CR to channel wall W can be as nearly constant in all radial directions as possible.

FIG. 23B shows two different cross-sectional views along analysis channel AC as viewed along cutlines A-A and B-B. Both cross-sectional views illustrate an aspect ratio approximating one. That is, for cross-section A-A, height H₁ of mixing channel MC is approximately equal to width W₁ of mixing channel MC, such that H₁/W₁ approximately equals one. Comparably, for cross-section B-B, height H₂ of mixing channel MC is approximately equal to width W₂ of mixing channel MC, such that H₂/W₂ approximately equals one.

FIG. 23B further shows that the cross-sectional area (H₂×W₂) of analysis region AR at cutline B-B, which is located at detection area DA of analysis region AR, is significantly larger than the cross-sectional area (H₁×W₁) of input end IE at cutline A-A. In some embodiments of the presently disclosed subject matter, the cross-sectional area at detection area DA can be at least twice the value of the cross-sectional area value at input end IE and further upstream, such as in mixing channel MC. Further, in some embodiments, the cross-sectional area at detection area DA can be between about two times and about ten times the value of the cross-sectional area value at input end IE. As shown in cutline B-B of FIG. 23B, detection area DA can be positioned along center analysis region CR approximately equidistant from each of walls W to provide maximal distance from walls W, and thereby minimize effects of molecule adsorption to walls W. It is clear from FIG. 23B that the larger cross-sectional area at cutline B-B can provide both greater distance from walls W and smaller S/V than the smaller cross-sectional area at cutline A-A, both of which can reduce adsorption effects on data analysis, as discussed herein. Although detection area DA is shown in the figures as a circle having a distinct diameter, the depiction in the drawings is not intended as a limitation to the size, shape, and/or location of detection area DA within the enlarged cross-sectional area of analysis region AR. Rather, detection area DA can be as large as necessary and shaped as necessary (e.g. circular, elongated oval or rectangle, etc.) to acquire the desired data, while minimizing size as much as possible to avoid deleterious adsorption effects on the data. Determination of the optimal balance of size, shape and location while minimizing adsorption effects is within the capabilities of one of ordinary skill in the art without requiring undue experimentation.

Additional details and features of analysis channel AC are disclosed in co-pending, commonly assigned U.S. Provisional Application entitled METHODS AND APPARATUSES FOR REDUCING EFFECTS OF MOLECULE ADSORPTION WITHIN MICROFLUIDIC CHANNELS, U.S. Provisional Application No. 60/707,366 (Attorney Docket No. 447/99/8), herein incorporated by reference in its entirety.

In some embodiments, the presently disclosed subject matter provides apparatuses and methods for making and using the same that can decrease the interference of adsorption to concentration dependent measurements, such as in biochemistry reactions (including IC₅₀ determinations), by reducing adsorption of molecules to microfluidic channel walls. In some embodiments, the presently disclosed subject matter provides microfluidic chips comprising channels and chambers with treated surfaces exhibiting reduced adsorption of molecules to channel walls, such as for example hydrophilic surfaces, and methods of preparing and using the same. In some embodiments, methods of preparing hydrophilic surfaces by treating hydrocarbon-based plastics, such as for example polycarbonate, with fluorine gas mixtures are provided. In some exemplary embodiments, the methods comprise contacting a mixture of fluorine gas and an inert gas with the surface to be treated, then flushing the surface with air. This treatment results in plastic surfaces of increased hydrophilicity (increased surface energy). Hydrophobic solutes, in particular known and potential drug compounds, in solutions in contact with these treated hydrophilic plastic surfaces are less likely to be adsorbed onto the more hydrophilic surfaces. Plastics comprising the treated surfaces are useful in providing many improved drug discovery and biochemical research devices for handling, storing, and testing solutions containing low concentrations of hydrophobic solutes.

Additional details and features of hydrophilic surfaces in microfluidic systems and methods of making and using the same are disclosed in co-pending, commonly owned U.S. Provisional Application entitled PLASTIC SURFACES AND APPARATUSES FOR REDUCED ADSORPTION OF SOLUTES AND METHODS OF PREPARING THE SAME, U.S. Provisional Application No. 60/707,288 (Attorney Docket No. 447/99/9).

Further, in some embodiments of the presently disclosed subject matter, microfluidic systems are provided comprising an analysis channel with an enlarged cross-sectional area and a reduced surface area to volume ratio and further comprising channels and chambers with hydrophilic surfaces.

It will be understood that various details of the present subject matter can be changed without departing from the scope of the present subject matter. Furthermore, the foregoing description is for the purpose of illustration only, and not for the purpose of limitation.

1. A microfluidic device for reducing concentration gradient noise in a fluid mix, the microfluidic device comprising:
(a) a plurality of microscale channels for passage of fluids;
(b) a mixing junction joining the plurality of channels and providing an area for fluids passing in the channels to combine into a fluid mix; and
(c) an expansion channel connected to the mixing junction, the expansion channel being adapted for passage of the fluid mix through the expansion channel to reduce concentration gradient noise of a fluid mix by dispersion of the fluid mix as the fluid mix passes through the expansion channel.

2. The microfluidic device of claim 1, wherein the mixing junction has a cross-sectional area between approximately 10 and 100,000 square micrometers.

3. The microfluidic device of claim 1, wherein the expansion channel has a length between approximately 0.005 and 10 millimeters.

4. The microfluidic device of claim 1, wherein the expansion channel has a cross-sectional area between approximately 2 to 500 times the cross-sectional area of the mixing junction.

5. The microfluidic device of claim 1, wherein the expansion channel has an at least substantially rectangular-shaped cross-section.

6. The microfluidic device of claim 5, wherein the ratio of the sides of the rectangular-shaped cross-section of the expansion channel is approximately 1.

7. The microfluidic device of claim 5, wherein the ratio of the sides of the rectangular-shaped cross-section of the expansion channel is between 2 and 10.

8. The microfluidic device of claim 1, wherein the expansion channel includes a tapered end connected to the mixing junction.

9. The microfluidic device of claim 1, wherein the expansion channel includes a tapered end opposing a distal end connected to the mixing junction.

10. The microfluidic device of claim 1, wherein the plurality of microscale channels comprise:
(a) a first microscale channel including first and second ends, wherein the first end of the first microscale channel is adapted for connection to a first pump and the second end of the first microscale channel is fluidly connected to the mixing junction; and
(b) a second microscale channel including first and second ends, wherein the first end of the second microscale channel is adapted for connection to a second pump and the second end of the second microscale channel is fluidly connected to the mixing junction.

11. The microfluidic device of claim 1, further comprising a connector channel connected to the mixing junction and the expansion channel for fluidly connecting the mixing junction and the expansion channel, wherein the connector channel has a length less than 20 centimeters.

12. The microfluidic device of claim 11, wherein the connector channel is a serpentine channel.

13. The microfluidic device of claim 1, wherein the mixing junction and the expansion channel are fabricated in a substrate.

14. The microfluidic device of claim 13, wherein the substrate comprises a polymer.

15. The microfluidic device of claim 13, wherein the substrate comprises a material selected from the group consisting of silicon, silica, glass, quartz, sapphire, zinc oxide, alumina, Group III-V compounds, and combinations thereof.

16-59. (canceled)

60. A method for reducing concentration gradient noise in a fluid mix, the method comprising:
(a) passing fluids in a plurality of microscale channels;
(b) combining the fluids into a common fluid flow in a mixing junction connecting the microscale channels;
(c) passing the common fluid flow through a connector channel to laterally mix the fluids; and
(d) passing the fluid mix through an expansion channel to reduce concentration gradient noise of the fluid mix by dispersion of the fluid mix as the fluid mix passes through the expansion channel.

61. A microfluidic system, comprising:
(a) a microfluidic chip, comprising:
(i) a mixing junction including an area for combining first and second fluids into a common fluid mix; and
(ii) an expansion channel connected to the mixing junction, the expansion channel being adapted for passage of the fluid flow through the expansion channel to reduce the concentration gradient noise of the fluid mix by dispersion of the fluid mix as the fluid mix advances through the expansion channel;
(b) a first pump connected to the mixing junction for advancing the first fluid to the expansion channel; and
(c) a second pump connected to the mixing junction for advancing the second fluid to the expansion channel.

62-144. (canceled)

145. A microfluidic device for reducing concentration gradient noise in a fluid mix, the microfluidic device comprising:
(a) a plurality of microscale channels for passage of fluids;
(b) a mixing junction joining the plurality of channels and providing an area for fluids passing in the channels to combine into a common fluid flow;
(c) a connector channel including first and second ends, the first end of the connector channel being connected to the mixing junction, the connector channel being adapted for passage of the common fluid flow through the connector channel to laterally mix the fluids; and
(d) a mixing channel comprising a series of outpockets connected to the second end of the connector channel, the mixing channel being adapted for passage of the fluid mix through the series of outpockets to reduce concentration gradient noise of a fluid mix by dispersion of the fluid mix as the fluid mix passes through the mixing channel.

146-150. (canceled)
